(19) United States
(12) Patent Application Publication
(10) Pub. No.: US 2025/0275361 A1
(43) Pub. Date: Aug. 28, 2025

(54) THIN-FILM TRANSISTOR SUBSTRATE AND DISPLAY APPARATUS INCLUDING THE SAME

(71) Applicant: Samsung Display Co., Ltd., Yongin-si (KR)

(72) Inventor: Heechul Lee, Yongin-si (KR)

(21) Appl. No.: 18/929,902

(22) Filed: Oct. 29, 2024

(30) Foreign Application Priority Data
Feb. 26, 2024 (KR) 10-2024-0027503

(51) Int. Cl. H10K 59/121; H10K 77/10; H10K 102/00

(52) U.S. Cl. CPC H10K 59/1213; H10K 77/111; H10K 2102/311

(57) ABSTRACT

A thin-film transistor substrate includes a substrate, a semiconductor layer disposed on the substrate, and a gate electrode disposed on the semiconductor layer, where the substrate includes a first substrate, a second substrate disposed opposite to the first substrate, a substrate intermediate layer interposed between the first substrate and the second substrate, a first intermediate electrode interposed between the substrate intermediate layer and the first substrate and corresponding to the gate electrode, and a second intermediate electrode interposed between the substrate intermediate layer and the second substrate and corresponding to the gate electrode.

This application claims priority to Korean Patent Application No. 10-2024-0027503, filed on Feb. 26, 2024, and all the benefits accruing therefrom under 35 U.S.C. § 119, the content of which in its entirety is herein incorporated by reference.

### BACKGROUND

### 1. Field

One or more embodiments relate to a thin-film transistor substrate and a display apparatus including the thin-film transistor substrate, and more particularly, to a thin-film transistor substrate in which the influence of light from the outside is reduced and a display apparatus including the thin-film transistor substrate.

### 2. Description of the Related Art

Generally, display apparatuses include display elements and pixel circuits electrically connected to the display elements, respectively, and each of the pixel circuits includes a thin-film transistor, etc. The pixel circuit may control the level of light emission of a display element electrically connected thereto, and thus, images may be displayed in a display area.

### SUMMARY

However, in a conventional display apparatus, the quality of displayed images may be lowered due to the influence of light from the outside.

One or more embodiments include a thin-film transistor substrate in which the influence of light from the outside is reduced and a display apparatus including the thin-film transistor substrate.

According to one or more embodiments, a thin-film transistor substrate includes a substrate, a semiconductor layer disposed on the substrate, and a gate electrode disposed on the semiconductor layer, where the substrate includes a first substrate, a second substrate disposed opposite to the first substrate, a substrate intermediate layer interposed between the first substrate and the second substrate, a first intermediate electrode interposed between the substrate intermediate layer and the first substrate and corresponding to the gate electrode, and a second intermediate electrode interposed between the substrate intermediate layer and the second substrate and corresponding to the gate electrode.

In an embodiment, each of the first intermediate electrode and the second intermediate electrode may overlap the gate electrode when viewed in a direction perpendicular to the substrate.

In an embodiment, the gate electrode may be located within the second intermediate electrode when viewed in the direction perpendicular to the substrate.

In an embodiment, when viewed in the direction perpendicular to the substrate, a portion of an edge of the gate electrode may overlap the semiconductor layer and the portion of the edge of the gate electrode may overlap an edge of the second intermediate electrode.

In an embodiment, the substrate intermediate layer may include amorphous silicon or crystalline silicon.

In an embodiment, electrical signals may be applied to the first intermediate electrode and the second intermediate electrode, and a polarity of an electrical signal applied to the first intermediate electrode may be different from a polarity of an electrical signal applied to the second intermediate electrode.

In an embodiment, electrical signals may be applied to the first intermediate electrode and the second intermediate electrode, and a potential of an electrical signal applied to the first intermediate electrode may be different from a potential of an electrical signal applied to the second intermediate electrode.

In an embodiment, electrical signals may be applied to the first intermediate electrode and the second intermediate electrode while a transistor including the semiconductor layer and the gate electrode is turned on.

In an embodiment, a polarity of an electrical signal applied to the first intermediate electrode may be alternately changed during a period from a time point at which the transistor is turned on to a time point at which the transistor is turned off.

In an embodiment, a polarity of an electrical signal applied to the second intermediate electrode may be opposite to the polarity of the electrical signal applied to the first intermediate electrode.

In an embodiment, a potential of an electrical signal applied to the first intermediate electrode may be alternately changed during a period from a time point at which the transistor is turned on to a time point at which the transistor is turned off.

In an embodiment, the potential of the electrical signal applied to the first intermediate electrode may be alternately changed between a first potential and a second potential, where, when the potential of the electrical signal applied to the first intermediate electrode is the first potential, the potential of the electrical signal applied to the second intermediate electrode may be the second potential, and when the potential of the electrical signal applied to the first intermediate electrode is the second potential, the potential of the electrical signal applied to the second intermediate electrode may be the first potential.

According to one or more embodiments, a display apparatus includes the thin-film transistor substrate described above, and a pixel electrode electrically connected to the semiconductor layer.

In an embodiment, the pixel electrode may be electrically connected to a conductive layer which contacts the semiconductor layer.

In an embodiment, the semiconductor layer and the gate electrode may be included in a driving transistor.

In an embodiment, the substrate may include a display area and a peripheral area outside the display area, the display apparatus may further include a driving driver located in the peripheral area, and the first intermediate electrode and the second intermediate electrode may be electrically connected to the driving driver.

In an embodiment, the driving driver may apply a first electrical signal to the first intermediate electrode and a second electrical signal to the second intermediate electrode, where a polarity of the first electrical signal may be different from a polarity of the second electrical signal.

In an embodiment, the driving driver may apply a first electrical signal to the first intermediate electrode and a second electrical signal to the second intermediate electrode, where a potential of the first electrical signal may be different from a potential of the second electrical signal.

In an embodiment, the driving driver may apply a first electrical signal to the first intermediate electrode and a second electrical signal to the second intermediate electrode while a transistor including the semiconductor layer and a gate electrode is turned on. In an embodiment, the driving driver may apply an electrical signal having an alternately changing polarity to the first intermediate electrode during a period from a time point at which the transistor is turned on to a time point at which the transistor is turned off.

In an embodiment, the driving driver may apply, to the second intermediate electrode, an electrical signal having a polarity opposite to the polarity of the electrical signal applied to the first intermediate electrode.

In an embodiment, the driving driver may apply, to the first intermediate electrode, an electrical signal having an alternately changing potential during a period from a time point at which the transistor is turned on to a time point at which the transistor is turned off.

In an embodiment, the alternately changing potential of the electrical signal is alternately changed between a first potential and a second potential, where the driving driver may apply an electrical signal having the second potential to the second intermediate electrode when the potential of the electrical signal applied to the first intermediate electrode is the first potential, and apply an electrical signal having the first potential to the second intermediate electrode when the potential of the electrical signal applied to the first intermediate electrode is the second potential.

These and/or other aspects will become apparent and more readily appreciated from the following description of the embodiments, the accompanying drawings, and claims.

### BRIEF DESCRIPTION OF THE DRAWINGS

The above and other features of certain embodiments of the disclosure will be more apparent from the following description taken in conjunction with the accompanying drawings, in which:

FIG. 1 is a plan view schematically illustrating some components included in a display apparatus according to an embodiment;

FIG. 2 is an equivalent circuit diagram of an embodiment of a pixel included in the display apparatus of FIG. 1;

FIG. 3 is a plan view schematically illustrating positions of transistors, capacitors, and the like in pixels included in the display apparatus of FIG. 1;

FIGS. 4 to 10 are plan views schematically illustrating elements, such as the transistors and the capacitors, of the display apparatus of FIG. 3 for each layer;

FIG. 11 is a cross-sectional view schematically illustrating a cross-section of the display apparatus of FIG. 3, taken along line I-l′;

FIG. 12 is a plan view schematically illustrating one component of a substrate included in the display apparatus of FIG. 1;

FIG. 13 is a waveform diagram schematically showing electrical signals that may be applied to components of FIG. 12 included in the display apparatus of FIG. 1;

FIG. 14 is a waveform diagram schematically showing electrical signals that may be applied to the equivalent circuit of FIG. 2 and the components of FIG. 12;

FIG. 15 is a plan view schematically illustrating some components included in a display apparatus according to an embodiment; and

FIG. 16 is a plan view schematically illustrating some components included in a display apparatus according to an embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

It will be understood that when a component, such as a layer, a film, a region, or a plate, is referred to as being “on” another component, the component may be directly on the other component or intervening components may be present therebetween. Sizes of components in the drawings may be exaggerated for convenience of explanation. For example, since sizes and thicknesses of components in the drawings are arbitrarily illustrated for convenience of explanation, the following embodiments are not limited thereto.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. Throughout the disclosure, the expression “at least one of a, b or c” or at least one selected from a, b and c″ indicates only a, only b, only c, both a and b, both a and c, both b and c, all of a, b, and c, or variations thereof. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

In the following embodiments, when layers, regions, or components are connected to each other, the layers, the regions, or the components may be directly connected to each other, or another layer, another region, or another component may be interposed between the layers, the regions, or the components and thus the layers, the regions, or the components may be indirectly connected to each other. For example, in the following embodiments, when layers, regions, or components are electrically connected to each other, the layers, the regions, or the components may be directly electrically connected to each other, or another layer, another region, or another component may be interposed between the layers, the regions, or the components and thus the layers, the regions, or the components may be indirectly electrically connected to each other.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, exemplary embodiments will be described in detail with reference to the accompanying drawings, and in the description with reference to the drawings, the same or corresponding constituents are indicated by the same reference numerals and any repetitive detailed descriptions thereof will be omitted or simplified.

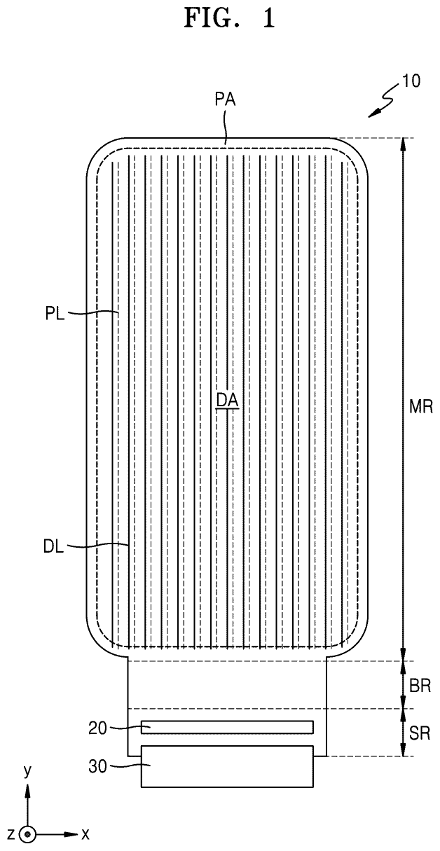

FIG. 1 is a plan view schematically illustrating some components included in a display apparatus according to an embodiment.

The display apparatus according to an embodiment may include a display panel 10. The display apparatus may be any of various types of display apparatus that include the display panel 10. In an embodiment, for example, the various types of display apparatus may include various products, such as smartphones, tablet computers, laptop computers, or portable televisions. The display panel 10 itself may be referred to as a display apparatus.

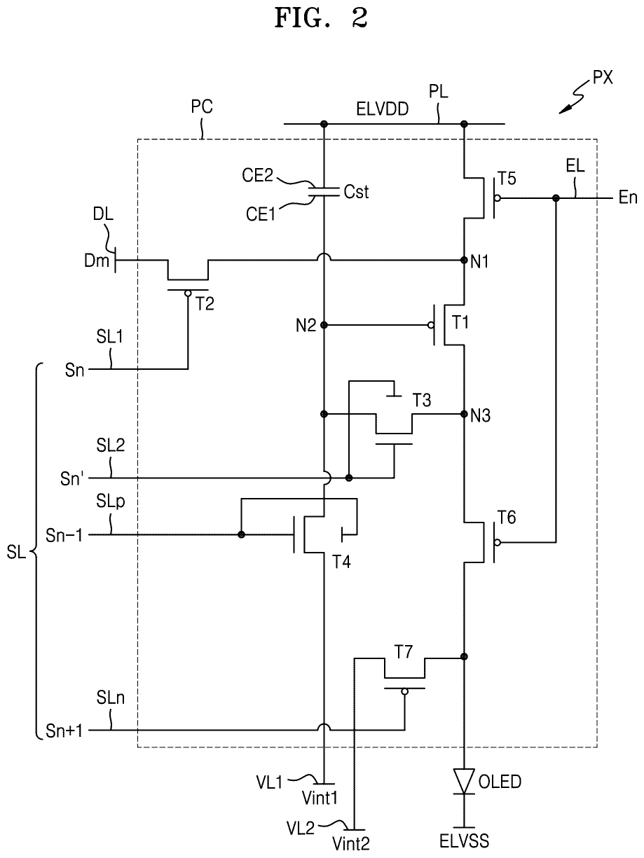

The display panel 10 may include a display area DA and a peripheral area PA outside the display area DA. The display area DA may include a portion in which an image is displayed, and a plurality of pixels (e.g., a pixel PX shown in FIG. 2) may be arranged in the display area DA. No pixel may be arranged in the peripheral area PA. When viewed in a direction approximately perpendicular to the display panel 10, the display panel 10 may have various shapes, such as a circle, an ellipse, a polygon, or a particular figure. In an embodiment, as shown in FIG. 1, the display area DA may have a substantially rectangular shape with round corners.

The peripheral area PA may be located outside the display area DA. The width (in an x-axis direction) of a portion of the second peripheral area PA2 may be less than the width (in the x-axis direction) of the display area DA. Through this structure, if desired, at least a portion of the second peripheral area PA2 may be easily bendable.

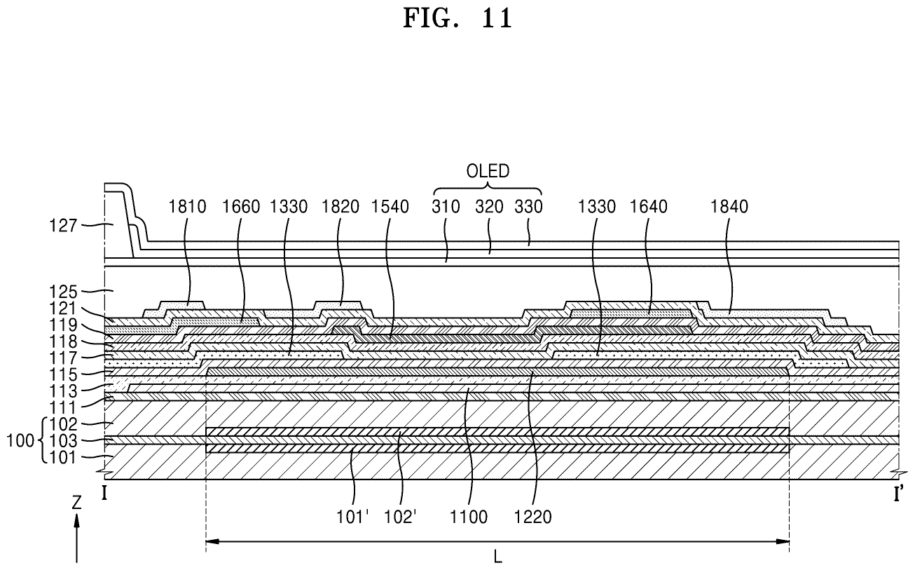

In an embodiment where the display panel 10 includes a substrate 100 (see FIG. 11), it may be stated that the substrate 100 includes the display area DA and the peripheral area PA. Hereinafter, for convenience of description, the substrate 100 will be described as including the display area DA and the peripheral area PA.

In the display area DA, a plurality of data lines DL may be arranged to cross the display area DA. Likewise, a plurality of power lines PL may be arranged in the display area DA to cross the display area DA. In FIG. 1, for convenience of illustration, the data lines DL are shown as solid lines and the power lines PL are shown as dotted lines. In an embodiment, the data lines DL and the power lines PL may be simultaneously formed in a same layer by using a same material.

In an embodiment, the display panel 10 may include a main area MR, a bending area BR outside the main area MR, and a sub area SR positioned on the opposite side of the main area MR around the bending area BR. In the bending area BR, the display panel 10 may be bent in a way such that at least a part of the sub area SR overlaps the main area MR when viewed in the z-axis direction. However, the disclosure is not limited to a bendable display apparatus and may be applicable to a display apparatus that is not bendable. The sub area SR may include a non-display area. By bending the display panel 10 in the bending area BR, when the display apparatus is viewed from the front (in the −z direction), the non-display area may not be visible, and even in a case in which the non-display area is visible, the visible area of the non-display area may be reduced.

A driving chip 20 or the like may be arranged in the sub area SR of the display panel 10. The driving chip 20 may include an integrated circuit configured to drive the display panel 10. That is, the driving chip 20 may be a driving driver. Additionally, the driving chip 20 may generate, in addition to data signals, electrical signals for driving or controlling a scan driving circuit and/or an emission control driving circuit and apply the electrical signals to the scan driving circuit and/or the emission control driving circuit. The driving chip 20 may be mounted in the sub area SR of the display panel 10. The driving chip 20 is mounted on a same surface as a display surface of the display area DA, but when the display panel 10 is bent in the bending area BR, as described above, the driving chip 20 may be located on the rear surface of the main area MR. In an embodiment, the scan driving circuit and/or the emission driving circuit may be located in the peripheral area PA, or may be located in the main area MR and have a shape extending in the y-axis direction.

A printed circuit board 30 or the like may be attached to an end of the sub area SR of the display panel 10. The printed circuit board 30 or the like may be electrically connected to the driving chip 20 or the like through a plurality of pads (not shown) arranged along one edge of the substrate.

Although an organic light-emitting display apparatus will hereinafter be described as an example of the display apparatus according to an embodiment, the display apparatus of the disclosure is not limited thereto. In another embodiment, the display apparatus of the disclosure may include a display apparatus, such as an inorganic light-emitting display apparatus (an inorganic light-emitting display or an inorganic electroluminescent (EL) display) or a quantum dot light-emitting display. For example, an emission layer of the display element included in the display apparatus may include an organic material or an inorganic material. In addition, the display apparatus may have an emission layer and a quantum dot layer in a path of light emitted from the emission layer.

As described above, the display panel 10 may include the substrate 100. Various elements included in the display panel 10 may be disposed over the substrate 100. The substrate 100 may include glass, metal, or polymer resin. In an embodiment where the display panel 10 is bent in the bending area BR, as described above, it may be desired that the substrate 100 is flexible or bendable. In such an embodiment, the substrate 100 may include polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate. The detailed configuration of the substrate 100 is described below.

A plurality of pixels may be in the display area DA. Each of the pixels refers to a sub-pixel and may include a display element, such as an organic light-emitting diode. The pixel may emit, for example, red, green, blue, or white light.

The pixel may be electrically connected to external circuits arranged in the peripheral area PA. In the peripheral area PA, a scan driving circuit, an emission control driving circuit, a terminal, a power supply line, a common voltage line, or the like may be arranged. The scan driving circuit may provide a scan signal to the pixel through a scan line. The emission control driving circuit may provide an emission control signal to the pixel through an emission control line. A pad (not shown) arranged in the peripheral area PA of the substrate 100 may be exposed without being covered by an insulating layer and be electrically connected to the printed circuit board 30. A terminal of the printed circuit board 30 may be electrically connected to a pad of the display panel 10.

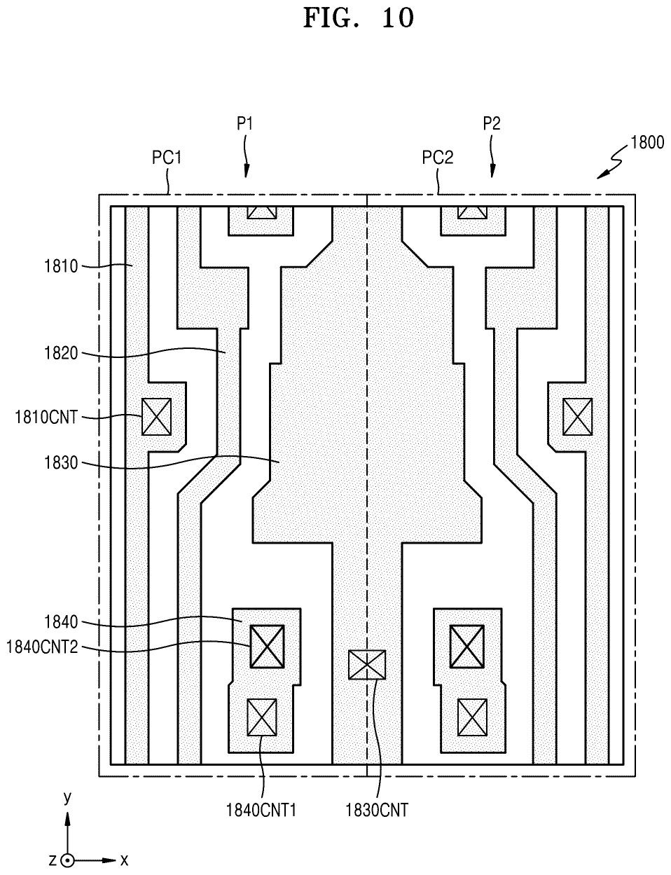

The printed circuit board 30 transmits a signal or power from a controller (not shown) to the display panel 10. Control signals generated by the controller may be transmitted to driving circuits through the printed circuit board 30. In addition, the controller may transmit a first power voltage ELVDD (shown in FIG. 2) to the power supply line and provide a second power voltage ELVSS (shown in FIG. 2) to the common voltage line. The first power voltage ELVDD, which is a driving voltage, may be transmitted to each pixel through a power line (see PL in FIGS. 1 and 1830 in FIG. 10) connected to the power supply line, and the second power voltage ELVSS, which is a common voltage, may be transmitted to an opposite electrode (see 330 in FIG. 11) of the pixel connected to the common voltage line. The common voltage line may have a loop shape with one side open, which is a part where the driving chip 20 and the like is located, and have a shape that partially surrounds the display area DA.

The controller may generate a data signal, and the generated data signal may be transmitted to the pixel through a driving chip 20 and a data line (see DL in FIGS. 1 and 1810 in FIG. 10).

For reference, “line” may refer to “wiring line.” The same applies to embodiments to be described below and modifications thereof.

FIG. 2 is an equivalent circuit diagram of an embodiment of a pixel PX included in the display panel of FIG. 1. As shown in FIG. 2, an embodiment of the pixel PX may include a pixel circuit PC and an organic light-emitting diode OLED electrically connected to the pixel circuit PC.

In an embodiment, the pixel circuit PC may include a plurality of thin-film transistors T1 to T7 and a storage capacitor Cst, as shown in FIG. 2. The plurality of thin-film transistors T1 to T7 and the storage capacitor Cst may be connected to signal lines SL1, SL2, SLp, SLn, EL, and DL, a first initialization voltage line VL1, a second initialization voltage line VL2, and a driving voltage line PL. At least one selected from these lines, for example, the driving voltage line PL, may be shared by neighboring pixels PX.

The plurality of thin-film transistors T1 to T7 may include a driving transistor T1, a switching transistor T2, a compensation transistor T3, a first initialization transistor T4, an operation control transistor T5, an emission control transistor T6, and a second initialization transistor T7.

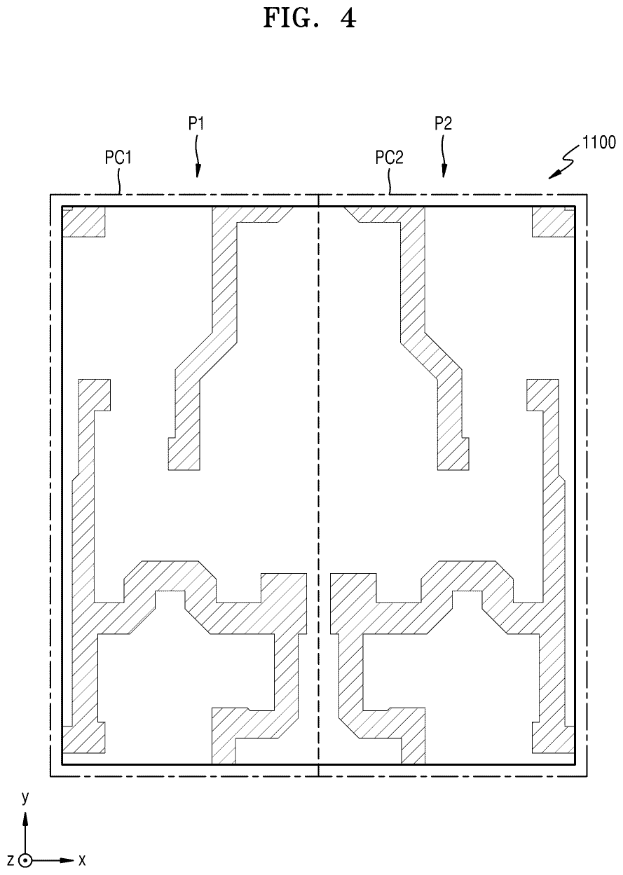

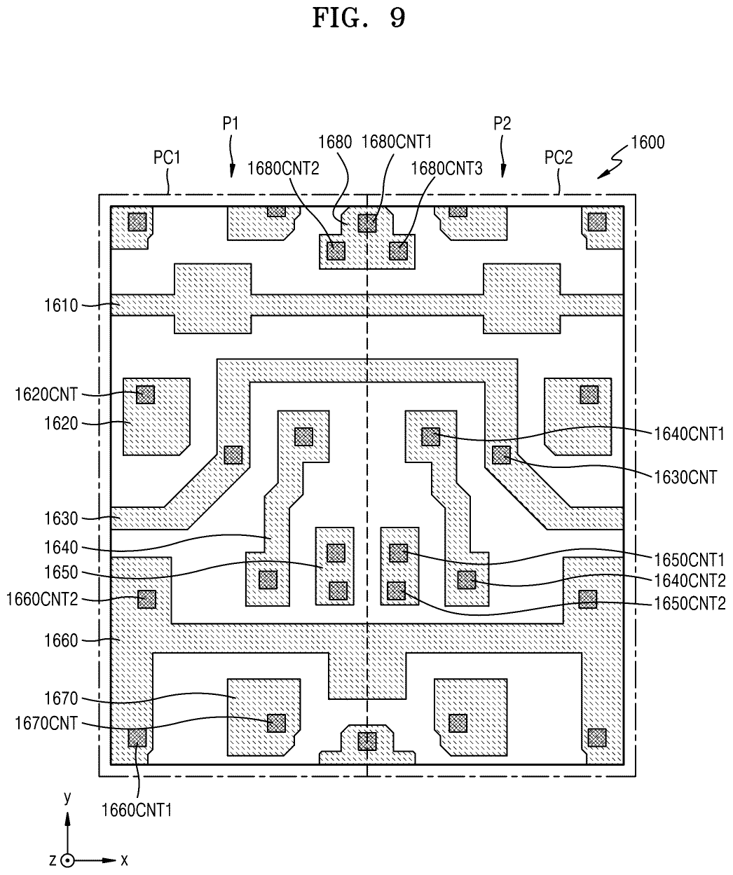

The organic light-emitting diode OLED may include a pixel electrode 310 (see FIG. 11) and an opposite electrode 330 (see FIG. 11). The pixel electrode 310 of the organic light-emitting diode OLED may be electrically connected to the driving transistor T1 via the emission control transistor T6 to receive driving current. That is, the pixel electrode 310 may be electrically connected to a sixth transmission line 1670 (see FIG. 9), which is a conductive layer that contacts a semiconductor layer 1100 (see FIG. 4), via a tenth transmission line 1840 (see FIG. 10), as described below. The opposite electrode 330 may receive a second power voltage ELVSS. The organic light-emitting diode OLED may generate light having a luminance corresponding to the driving current.

At least one of the plurality of thin-film transistors T1 to T7 may be n-channel metal-oxide-semiconductor field-effect-transistors (n-channel MOSFETs; NMOS), and the others of the plurality of thin-film transistors T1 to T7 may be p-channel MOSFETS (PMOS). In an embodiment, for example, the compensation transistor T3 and the first initialization transistor T4 from among the plurality of thin-film transistors T1 to T7 may be NMOS, and the other ones may be PMOS. In some embodiments, the compensation transistor T3, the first initialization transistor T4, and the second initialization transistor T7 from among the plurality of thin-film transistors T1 to T7 may be NMOS, and the others of the plurality of thin-film transistors T1 to T7 may be PMOS. In some embodiments, the plurality of thin-film transistors T1 to T7 may all be NMOS or all be PMOS. Each of the plurality of thin-film transistors T1 to T7 may include amorphous silicon or polysilicon. In an embodiment, a thin-film transistor as an NMOS may include an oxide semiconductor. Hereinafter, embodiments where the compensation transistor T3 and the first initialization transistor T4 are NMOS including an oxide semiconductor and the other of the plurality of thin-film transistors T1 to T7 are PMOS as shown in FIG. 2 will be mainly described, for convenience of description.

The signal lines may include a first scan line SL1 configured to transmit a first scan signal Sn to the switching transistor T2, a second scan line SL2 configured to transmit a second scan signal Sn′ to the compensation transistor T3, a previous scan line SLp configured to transmit a previous scan signal Sn−1 to the first initialization transistor T4, a next scan line SLn configured to transmit a next scan signal Sn+1 to the second initialization transistor T7, an emission control line EL configured to transmit an emission control signal En to the operation control transistor T5 and the emission control transistor T6, and a data line DL which crosses the first scan line SL1 and is configured to transmit a data signal Dm to the switching transistor T2.

The driving voltage line PL may transmit the driving voltage ELVDD to the driving transistor T1, the first initialization voltage line VL1 may transmit a first initialization voltage Vint1 to the first initialization transistor T4 for initializing the driving transistor T1, and the second initialization voltage line VL2 may transmit a second initialization voltage Vint2 to the second initialization transistor T7 for initializing the pixel electrode 310 of the organic light-emitting diode OLED.

A driving gate electrode of the driving transistor T1 may be connected to the storage capacitor Cst through a second node N2, where one of a source region and a drain region of the driving transistor T1 may be connected to the driving voltage line PL via the operation control transistor T5 through a first node N1, and the other of the source region and the drain region of the driving transistor T1 may be electrically connected to the pixel electrode 310 of the organic light-emitting diode OLED via the emission control transistor T6 through a third node N3. The driving transistor T1 may receive the data signal Dm based on a switching operation of the switching transistor T2 and supply a driving current to the organic light-emitting diode OLED. In other words, the driving transistor T1 may control an amount of current that flows to the organic light-emitting diode OLED from the first node N1 electrically connected to the driving voltage line PL, in response to a potential difference between the first node N1 and the second node N2, which varies depending on the data signal Dm.

A switching gate electrode of the switching transistor T2 may be connected to the first scan line SL1 configured to transmit the first scan signal Sn to the switching transistor T2, where one of a source region and a drain region of the switching transistor T2 may be connected to the data line DL, and the other of the source region and the drain region of the switching transistor T2 may be connected to the driving voltage line PL via the operation control transistor T5 and to the driving transistor T1 through the first node N1. In response to a voltage applied to the first scan line SL1, the switching transistor T2 may transmit the data signal Dm from the data line DL to the first node N1. In other words, the switching transistor T2 may be turned on in response to the first scan signal Sn received through the first scan line SL1 and perform a switching operation for transmitting the data signal Dm received via the data line DL to the driving transistor T1 through the first node N1.

A compensation gate electrode of the compensation transistor T3 may be connected to the second scan line SL2. One of a source region and a drain region of the compensation transistor T3 may be connected to the pixel electrode 310 of the organic light-emitting diode OLED via the emission control transistor T6 through the third node N3. The other of the source region and the drain region of the compensation transistor T3 may be connected to a first capacitor electrode CE1 of the storage capacitor Cst and the driving gate electrode of the driving transistor T1 through the second node N2. The compensation transistor T3 as described above may be turned on in response to the second scan signal Sn′ received through the second scan line SL2 and diode-connect the driving transistor T1.

A first initialization gate electrode of the first initialization transistor T4 may be connected to the previous scan line SLp. One of a source region and a drain region of the first initialization transistor T4 may be connected to the first initialization voltage line VL1. The other of the source region and the drain region of the first initialization transistor T4 may be connected to the first capacitor electrode CE1 of the storage capacitor Cst and the driving gate electrode of the driving transistor T1 through the second node N2. The first initialization transistor T4 may apply the first initialization voltage Vint1 to the second node N2 from the first initialization voltage line VL1, in response to a voltage applied to the previous scan line SLp. In other words, the first initialization transistor T4 may be turned on in response to the previous scan signal Sn−1 received through the previous scan line SLp and perform an initialization operation for applying the first initialization voltage Vint1 to the driving gate electrode of the driving transistor T1 and initializing a voltage of the driving gate electrode of the driving transistor T1.

An operation control gate electrode of the operation control transistor T5 may be connected to the emission control line EL, where one of a source region and a drain region of the operation control transistor T5 may be connected to the driving voltage line PL, and the other of the source region and the drain region of the operation control transistor T5 may be connected to the driving transistor T1 and the switching transistor T2 through the first node N1.

An emission control gate electrode of the emission control transistor T6 may be connected to the emission control line EL, where one of a source region and a drain region of the emission control transistor T6 may be connected to the driving transistor T1 and the compensation transistor T3 through the third node N3, and the other of the source region and the drain region of the emission control transistor T6 may be electrically connected to the pixel electrode 310 of the organic light-emitting diode OLED.

The operation control transistor T5 and the emission control transistor T6 may be simultaneously turned on in response to the emission control signal En received through the emission control line EL, and thus, the driving voltage ELVDD may be applied to the organic light-emitting diode OLED and a driving current may flow in the organic light-emitting diode OLED.

A second initialization gate electrode of the second initialization transistor T7 may be connected to the next scan line SLn, where one of a source region and a drain region of the second initialization transistor T7 may be connected to the pixel electrode 310 of the organic light-emitting diode OLED, and the other of the source region and the drain region of the second initialization transistor T7 may be connected to the second initialization transistor T7 and receive the second initialization voltage Vint2. The second initialization transistor T7 may be turned on in response to the next scan signal Sn+1 received through the next scan line SLn, and thus, the pixel electrode 310 of the organic light-emitting diode OLED may be initialized. In an embodiment, the next scan line SLn and the first scan line SL1 may be the same line as each other. In such an embodiment, the corresponding scan line may transmit the same electrical signal with a time difference and may function as the first scan line SL1 and also as the next scan line SLn. In other words, the next scan line SLn may include a first scan line of a pixel, which is adjacent to the pixel PX shown in FIG. 2, and electrically connected to the data line DL.

The second initialization transistor T7 may be connected to the first scan line SL1, as shown in FIG. 2. However, the disclosure is not limited thereto, and the second initialization transistor T7 may be connected to the emission control line EL and driven according to the emission control signal En.

The storage capacitor Cst may include the first capacitor electrode CE1 and a second capacitor electrode CE2. The first capacitor electrode CE1 of the storage capacitor Cst may be connected to the driving gate electrode of the driving transistor T1 through the second node N2, and the second capacitor electrode CE2 of the storage capacitor Cst may be connected to the driving voltage line PL. The storage capacitor Cst may store a charge corresponding to a voltage difference between the driving gate electrode voltage of the driving transistor T1 and the driving voltage ELVDD.

A detailed operation of each pixel PX according to an embodiment is described below.

During an initialization period, the previous scan signal Sn−1 is supplied through the previous scan line SLp, the next scan signal Sn+1 is supplied through the next scan line SLn, and the second scan signal Sn′ is supplied through the second scan line SL2. Accordingly, in response to the previous scan signal Sn−1, the first initialization transistor T4 is turned on, and thus, the driving transistor T1 is initialized by the first initialization voltage Vint1 supplied from the first initialization voltage line VL1. In addition, in response to the next scan signal Sn+1, the second initialization transistor T7 is turned on, and thus, the pixel electrode 310 of the organic light-emitting diode OLED is turned on by the second initialization voltage Vint2 supplied from the second initialization voltage line VL2. In addition, the compensation transistor T3 is turned on by the second scan signal Sn′, and the driving transistor T1 is diode-connected by the turned-on compensation transistor T3 and is biased in a forward direction.

For reference, the fact that the previous scan signal Sn−1 is supplied through the previous scan line SLp means that a signal that turns on the first initialization transistor T4 is supplied. For example, in a case where the first initialization transistor T4 is NMOS, the fact that the previous scan signal Sn−1 is supplied through the previous scan line SLp means that a high signal is supplied through the previous scan line SLp. Likewise, the fact that the next scan signal Sn+1 is supplied through the next scan line SLn means that a signal that turns on the second initialization transistor T7 is supplied. For example, in a case where the second initialization transistor T7 is PMOS, the fact that the next scan signal Sn+1 is supplied through the next scan line SLn means that a low signal is supplied through the next scan line SLn. The same applies to other scan signals.

During a data programming period, when the first scan signal Sn is supplied through the first scan line SL1, the switching transistor T2 is turned on in response to the first scan signal Sn. The second scan signal Sn′ also continues to be supplied through the second scan line SL2 to keep the compensation transistor T3 turned on, and thus, the driving transistor T1 continues to be diode-connected and forward biased. Then, a compensation voltage (Dm+Vth, where Vth has a negative value), which is obtained by subtracting a threshold voltage (Vth) of the driving transistor T1 from the data signal Dm received through the data line DL, may be applied to the driving gate electrode of the driving transistor T1. The driving voltage ELVDD and the compensation voltage (Dm+Vth) are respectively applied to opposite ends of the storage capacitor Cst, and a charge corresponding to a voltage difference between the opposite ends of the storage capacitor Cst may be stored in the storage capacitor Cst.

During an emission period, the operation control transistor T5 and the emission control transistor T6 may be turned on in response to the emission control signal En received through the emission control line EL. A driving current corresponding to a voltage difference between the voltage of the driving gate electrode of the driving transistor T1 and the driving voltage ELVDD may be generated, and the driving current may be supplied to the organic light-emitting diode OLED through the emission control transistor T6.

As described above, some of the plurality of thin-film transistors T1 to T7 may include an oxide semiconductor. In an embodiment, for example, the compensation transistor T3 and the first initialization transistor T4 may include an oxide semiconductor.

In a case of a thin-film transistor including polysilicon, which is highly reliable, the thin-film transistor may be precisely controlled so that an intended current flows. Accordingly, in an embodiment where a semiconductor layer including highly-reliable polysilicon is included in the driving transistor T1 that directly affects a brightness of the display apparatus, a high-resolution display apparatus may be implemented. In addition, an oxide semiconductor has high carrier mobility and low leakage current, and thus, a voltage drop is not large even when a driving time is long. In other words, in an oxide semiconductor, a change in color of an image according to a voltage drop is not large even when the display apparatus is driven at low frequencies, and thus, the display apparatus may be driven at low frequencies. Accordingly, in an embodiment, the compensation transistor T3 and the first initialization transistor T4 include an oxide semiconductor, such that a display apparatus with reduced power consumption while preventing leakage current may be implemented.

Such an oxide semiconductor may be sensitive to light, and thus, an amount of current or the like may vary depending on external light. Accordingly, in an embodiment, a metal layer may be disposed under the oxide semiconductor and absorb or reflect the external light. Accordingly, as shown in FIG. 2, in each of the compensation transistor T3 and the first initialization transistor T4 including the oxide semiconductor, a gate electrode may be disposed over and below an oxide semiconductor layer. In other words, when viewed in the direction (the z-axis direction) perpendicular to the upper surface of the substrate 100, that is a thickness direction of the substrate 100, the metal layer disposed under the oxide semiconductor may overlap the oxide semiconductor.

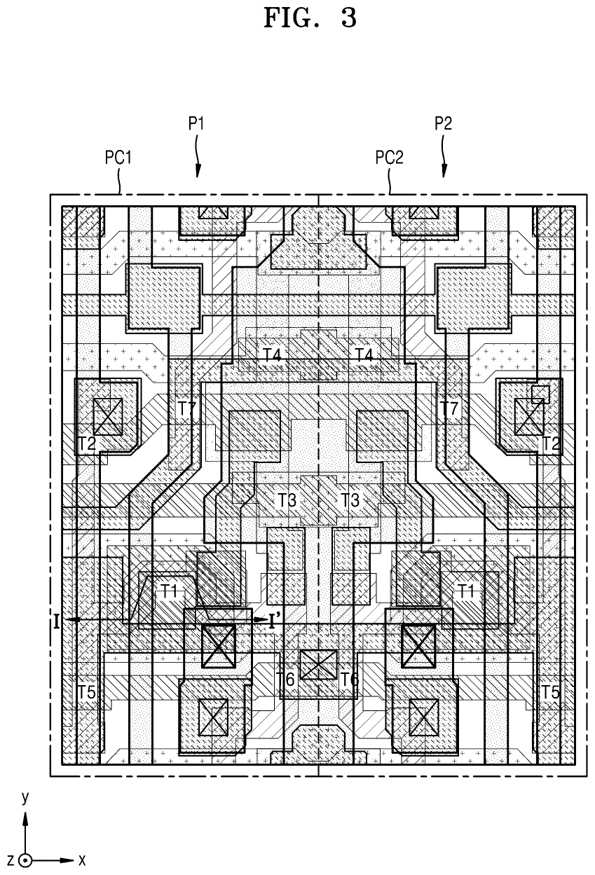

FIG. 3 is a plan view schematically illustrating positions of transistors, capacitors, and the like in pixels included in the display panel of FIG. 1, FIGS. 4 to 10 are plan views schematically illustrating elements, such as the transistors and the capacitors, of the display panel shown in FIG. 3 for each layer, and FIG. 11 is a cross-sectional view schematically illustrating a cross-section of the display panel of FIG. 3, taken along line I-I′.

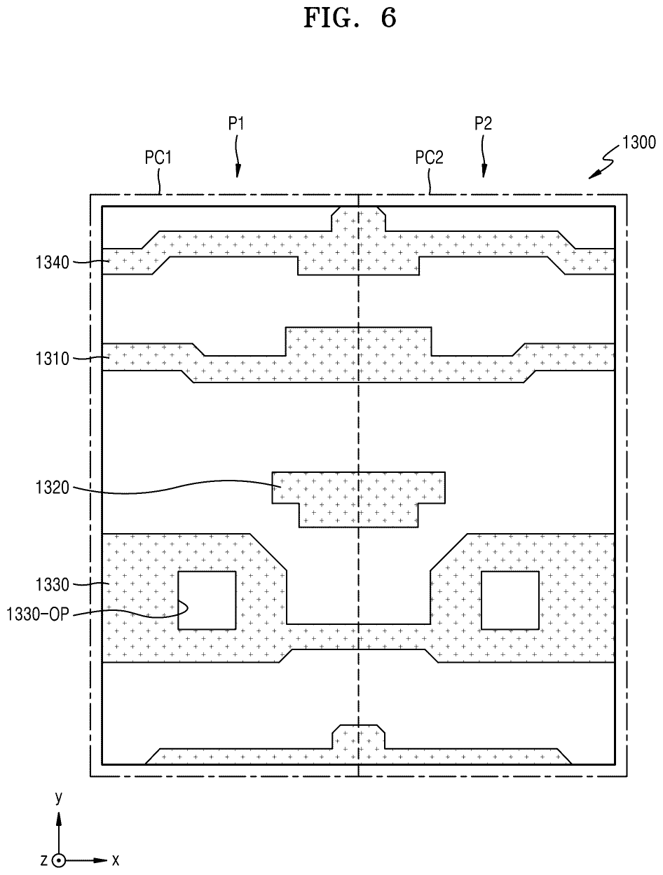

As shown in these drawings, an embodiment of the display apparatus may include a first pixel P1 and a second pixel P2 that are adjacent to each other. The first pixel P1 and the second pixel P2 may be symmetrical to each other with respect to an imaginary line, as shown in FIG. 6, etc. However, the disclosure is not limited thereto, and the first pixel P1 and the second pixel P2 may have a same structure rather than a symmetrical structure. The first pixel P1 may include a first pixel circuit PC1, and the second pixel P2 may include a second pixel circuit PC2. Hereinafter, for convenience of description, some conductive patterns are described based on the first pixel circuit PC1, but these conductive patterns may also be substantially symmetrically arranged in the second pixel circuit PC2. The first pixel circuit PC1 or the second pixel circuit PC2 refers to a pixel circuit in a pixel located in the display area DA in FIG. 1. A display element may be electrically connected to each of the first pixel circuit PC1 and the second pixel circuit PC2. The display element may be, for example, an organic light-emitting element, that is, the organic light-emitting diode OLED.

A buffer layer 111 (see FIG. 11) including silicon oxide, silicon nitride, or silicon oxynitride may be disposed on the substrate 100. The buffer layer 111 may effectively prevent diffusion of metal atoms or impurities from the substrate 100 toward the first semiconductor layer 1100 disposed thereon. In addition, during a crystallization process of forming the first semiconductor layer 1100 on the substrate 100, the buffer layer 111 may adjust a rate at which heat is provided, and thus, the first semiconductor layer 1100 is uniformly crystallized.

The first semiconductor layer 1100 shown in FIG. 4 may be disposed on the buffer layer 111. The first semiconductor layer 1100 may include a silicon semiconductor. In an embodiment, for example, the first semiconductor layer 1100 may include amorphous silicon or polysilicon. In an embodiment, for example, the first semiconductor layer 1100 may include polysilicon crystallized at a low temperature. In an embodiment, ions may be injected into at least a portion of the first semiconductor layer 1100.

In an embodiment where the driving transistor T1, the switching transistor T2, the operation control transistor T5, the emission control transistor T6, and the second initialization transistor T7 may be PMOS, as described above, these thin-film transistors may be located along the first semiconductor layer 1100 shown in FIG. 4.

The first gate insulating layer 113 (see FIG. 11) may be disposed over the substrate 100 and cover the first semiconductor layer 1100. The first gate insulating layer 113 may include an insulating material. In an embodiment, for example, the first gate insulating layer 113 may include silicon oxide, silicon nitride, silicon oxynitride, aluminum oxide, or the like.

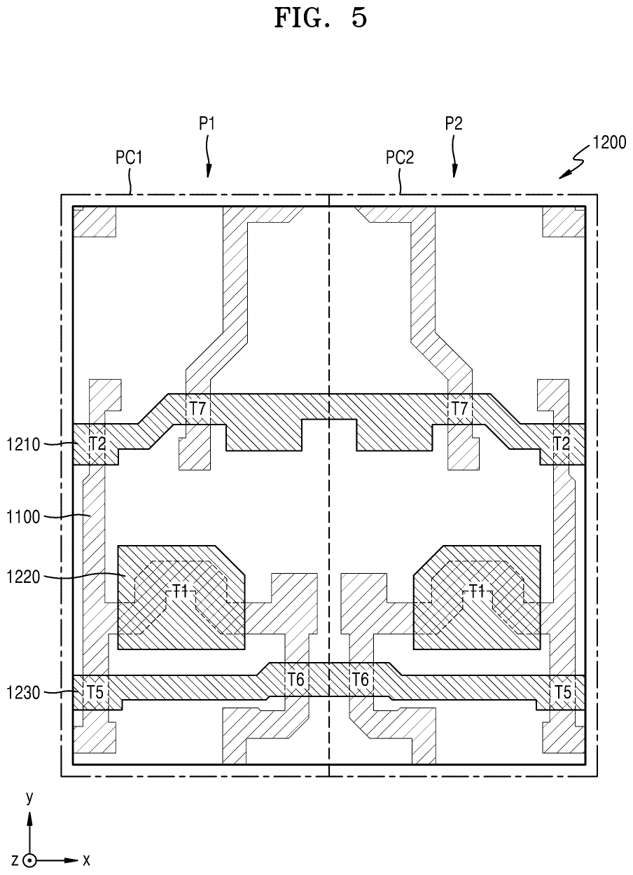

The first gate layer 1200 shown in FIG. 5 may be disposed on the first gate insulating layer 113. In FIG. 5, the first semiconductor layer 1100 is shown together with the first gate layer 1200, for convenience of description. The first gate layer 1200 may include a first gate line 1210, a first gate electrode 1220, and a second gate line 1230.

The first gate line 1210 may extend in a second direction (the x-axis direction). The first gate line 1210 may be the first scan line SL1 or the next scan line SLn in FIG. 2. In other words, in the first pixel P1 shown in FIG. 5, the first gate line 1210 may correspond to the first scan line SL1 in FIG. 2, and in a pixel adjacent to the first pixel P1 in the +y direction, the first gate line 1210 may correspond to the next scan line SLn in FIG. 2. Accordingly, the first scan signal Sn or the next scan signal Sn+1 may be applied to the pixels through the first gate line 1210. Portions of the first gate line 1210 overlapping the first semiconductor layer 1100 may include or define the switching gate electrode of the switching transistor T2 and the second initialization gate electrode of the second initialization transistor T7.

The first gate electrode 1220 may have an isolated shape. The first gate electrode 1220 may include the driving gate electrode of the driving transistor T1. For reference, a portion of the first semiconductor layer 1100 overlapping the first gate electrode 1220 and a portion therearound may be referred to as a driving semiconductor layer.

The second gate line 1230 may extend in the second direction (the x-axis direction). The second gate line 1230 may correspond to the emission control line EL in FIG. 2. Portions of the second gate line 1230 overlapping the first semiconductor layer 1100 may include or define the operation control gate electrode of the operation control transistor T5 and the emission control gate electrode of the emission control transistor T6. The emission control signal En may be applied to the pixels through the second gate line 1230.

The first gate layer 1200 may include a metal, an alloy, a conductive metal oxide, a transparent conductive material, or the like. In an embodiment, for example, the first gate layer 1200 may include silver (Ag), an Ag-containing alloy, molybdenum (Mo), a Mo-containing alloy, aluminum (Al), an Al-containing alloy, an aluminum nitride (AlN), tungsten (W), a tungsten nitride (WN), copper (Cu), nickel (Ni), chromium (Cr), a chromium nitride (CrN), titanium (Ti), tantalum (Ta), platinum (Pt), scandium (Sc), an indium tin oxide (ITO), an indium zinc oxide (IZO), or the like. The first gate layer 1200 may have a multi-layer structure, such as a two-layer structure of a Mo layer and an Al layer, or a three-layer structure of a Mo layer, an Al layer, and another Mo layer.

A second gate insulating layer 115 (see FIG. 11) may be disposed on the first gate insulating layer 113 and cover the first gate layer 1200. The second gate insulating layer 115 may include a same/similar insulating material as/to the first gate insulating layer 113.

A second gate layer 1300 shown in FIG. 6 may be disposed on the second gate insulating layer 115. The second gate layer 1300 may include a third gate line 1310, a fourth gate line 1320, a capacitor upper electrode 1330, and a first initialization voltage line 1340 (i.e., the first initialization voltage line VL1 in FIG. 2).

The third gate line 1310 may extend in the second direction (the x-axis direction). The third gate line 1310 may correspond to the previous scan line SLp in FIG. 2. When viewed in the direction (the z-axis direction) perpendicular to the substrate 100, the third gate line 1310 may be apart from the first gate line 1210. The previous scan signal Sn−1 may be applied to the pixels through the third gate line 1310. A portion of the third gate line 1310 overlapping a second semiconductor layer 1400 to be described below may include or define a first initialization lower gate electrode of the first initialization transistor T4.

The fourth gate line 1320 may also extend in the second direction (the x-axis direction and may have an isolated shape. The fourth gate line 1320 may be electrically connected to a sixth gate line 1530 described below and correspond to the second scan line SL2 in FIG. 2. When viewed in the direction (the z-axis direction) perpendicular to the substrate 100, the fourth gate line 1320 may be apart from the first gate line 1210 and the third gate line 1310. The second scan signal Sn′ may be applied to the pixels through the fourth gate line 1320. A portion of the fourth gate line 1320 overlapping the second semiconductor layer 1400 to be described below may include or define a compensation lower gate electrode of the compensation transistor T3.

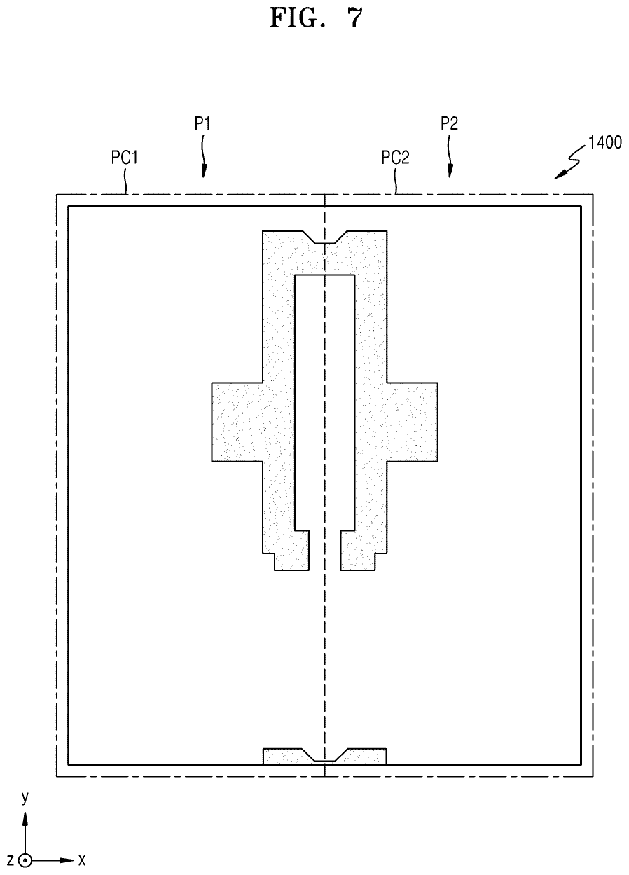

The third gate line 1310 and the fourth gate line 1320 may be disposed under the second semiconductor layer 1400 to be described below with reference to FIG. 7 and may function as gate electrodes and also as lower protective metals for protecting portions of the second semiconductor layer 1400 overlapping the third gate line 1310 and the fourth gate line 1320.

The capacitor upper electrode 1330 may overlap the first gate electrode 1220 and extend in the second direction (the x-axis direction). The capacitor upper electrode 1330 described above may constitute the storage capacitor Cst together with the first gate electrode 1220, to correspond to the second capacitor electrode CE2 in FIG. 2. The driving voltage ELVDD may be applied to the capacitor upper electrode 1330. In addition, a hole may be defined in the capacitor upper electrode 1330, and at least a portion of the first gate electrode 1220 may overlap the hole.

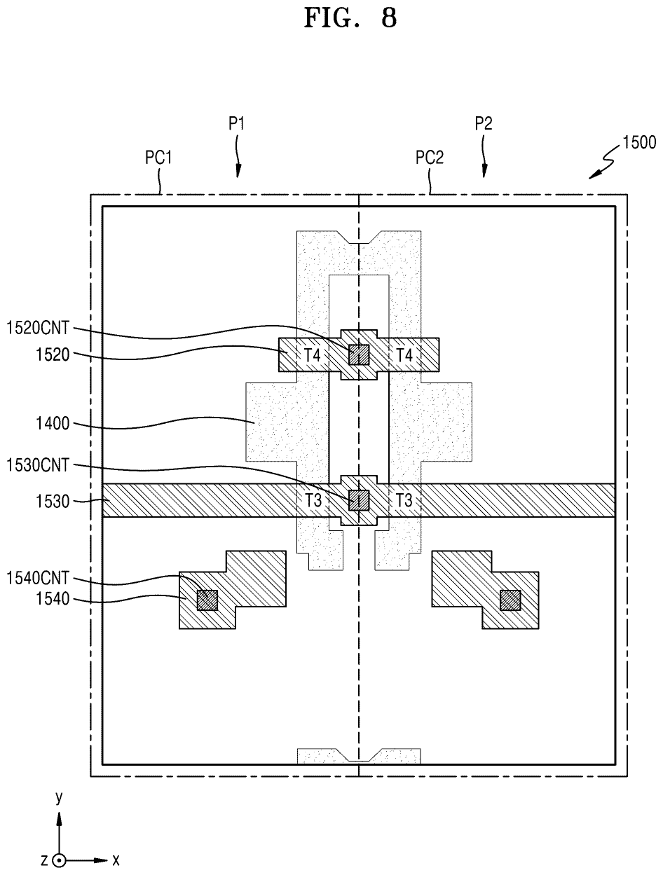

The first initialization voltage line 1340 corresponding to the first initialization voltage line VL1 in FIG. 2 may extend in the second direction (the x-axis direction). When viewed in the direction (the z-axis direction) perpendicular to the substrate 100, the first initialization voltage line 1340 may be apart from the third gate line 1310. The first initialization voltage Vint1 may be applied to the pixels through the first initialization voltage line 1340. The first initialization voltage line 1340 may at least partially overlap the second semiconductor layer 1400 to be described below and may apply the first initialization voltage line 1340 to the second semiconductor layer 1400. The first initialization voltage line 1340 may be electrically connected to the second semiconductor layer 1400 through contact holes 1680CNT1, 1680CNT2, and 1680CNT3 to be described below with reference to FIG. 8.

The second gate layer 1300 may include a metal, an alloy, a conductive metal oxide, a transparent conductive material, or the like. In an embodiment, for example, the second gate layer 1300 may include Ag, an Ag-containing alloy, Mo, a Mo-containing alloy, Al, an Al-containing alloy, AlN, W, WN, Cu, Ni, Cr, CrN, Ti, Ta, Pt, Sc, ITO, or IZO. The second gate layer 1300 may have a multi-layer structure, such as a two-layer structure of a Mo layer and an Al layer, or a three-layer structure of a Mo layer, an Al layer, and another Mo layer.

A first interlayer insulating layer 117 (see FIG. 11) may be disposed on the second gate insulating layer 115 and cover the second gate layer 1300. The first interlayer insulating layer 117 may include an insulating material. In an embodiment, for example, the first interlayer insulating layer 117 may include silicon oxide, silicon nitride, silicon oxynitride, aluminum oxide, or the like.

The second semiconductor layer 1400 shown in FIG. 7 may be disposed on the first interlayer insulating layer 117. In an embodiment, as described above, the second semiconductor layer 1400 may include an oxide semiconductor. The second semiconductor layer 1400 may be disposed in a layer different from a layer in which the first semiconductor layer 1100 is disposed, and may not overlap the first semiconductor layer 1100 when viewed in the direction (the z-axis direction) perpendicular to the substrate 100.

The third gate insulating layer 118 may be disposed on the first interlayer insulating layer 117 and cover the second semiconductor layer 1400. The third gate insulating layer 118 may include an insulating material. In another embodiment, unlike shown in FIG. 11, the third gate insulating layer 118 may be disposed only on a portion of the second semiconductor layer 1400 and not on the first interlayer insulating layer 117. In such an embodiment, the third gate insulating layer 118 may have a same pattern as a third gate layer 1500 to be described below with reference to FIG. 8. In other words, when viewed in the direction (the z-axis direction) perpendicular to the substrate 100, the third gate insulating layer 118 may completely or almost completely overlap the third gate layer 1500. This may be implemented by simultaneously patterning the third gate insulating layer 118 and the third gate layer 1500. In such an embodiment, in the second semiconductor layer 1400, source regions and drain regions other than channel regions overlapping the third gate layer 1500 may not be covered with the third gate insulating layer 118 and may be in direct contact with the second interlayer insulating layer 119. In an embodiment, for example, the third gate insulating layer 118 may include silicon oxide, silicon nitride, silicon oxynitride, aluminum oxide, or the like.

The third gate layer 1500 shown in FIG. 8 may be disposed on the third gate insulating layer 118. The third gate layer 1500 may include a fifth gate line 1520, a sixth gate line 1530, and a first transmission line 1540.

The fifth gate line 1520 may extend approximately in the second direction (the x-axis direction) and may have an isolated shape. When viewed in the direction (the z-axis direction) perpendicular to the substrate 100, the fifth gate line 1520 may overlap the third gate line 1310. A portion of the fifth gate line 1520 overlapping the second semiconductor layer 1400 may include or define a first initialization upper gate electrode of the first initialization transistor T4. A portion of the second semiconductor layer 1400 overlapping the fifth gate line 1520 and a portion therearound may be referred to as a first initialization semiconductor layer. The fifth gate line 1520 may be electrically connected to the third gate line 1310. In an embodiment, for example, the fifth gate line 1520 may be electrically connected to the third gate line 1310 through a contact hole 1520CNT defined in an insulating layer between the fifth gate line 1520 and the third gate line 1310. Accordingly, the fifth gate line 1520 may correspond to the previous scan line SLp of FIG. 2 together with the third gate line 1310. Accordingly, the previous scan signal Sn−1 may be applied to pixels through the fifth gate line 1520 and/or the third gate line 1310.

The sixth gate line 1530 may extend in the second direction (the x-axis direction). When viewed in the direction (the z-axis direction) perpendicular to the substrate 100, the sixth gate line 1530 may overlap the fourth gate line 1320. A portion of the sixth gate line 1530 overlapping the second semiconductor layer 1400 may include or define a compensation upper gate electrode of the compensation transistor T3. The sixth gate line 1530 may be electrically connected to the fourth gate line 1320. In an embodiment, for example, the sixth gate line 1530 may be electrically connected to the fourth gate line 1320 through a contact hole 1530CNT defined in an insulating layer between the sixth gate line 1530 and the fourth gate line 1320. Accordingly, the sixth gate line 1530 may correspond to the second scan line SL2 of FIG. 2 together with the fourth gate line 1320. Accordingly, the second scan signal Sn′ may be applied to pixels through the sixth gate line 1530 and/or the fourth gate line 1320.

The first transmission line 1540 may be electrically connected to the first gate electrode 1220, which is a driving gate electrode, through the contact hole 1540CNT defined or formed through an opening 1330-OP of the capacitor upper electrode 1330. The first transmission line 1540 may transmit, to the first gate electrode 1220, the first initialization voltage Vint1 transmitted through the first initialization transistor T4.

The third gate layer 1500 may include a metal, an alloy, a conductive metal oxide, a transparent conductive material, or the like. In an embodiment, for example, the third gate layer 1500 may include Ag, an Ag-containing alloy, Mo, a Mo-containing alloy, Al, an Al-containing alloy, AlN, W, WN, Cu, Ni, Cr, CrN, Ti, Ta, Pt, Sc, ITO, IZO, or the like. The third gate layer 1500 may have a multi-layer structure, such as a two-layer structure of a Mo layer and an Al layer, or a three-layer structure of a Mo layer, an Al layer, and another Mo layer.

The second interlayer insulating layer 119 (see FIG. 11) may cover at least a portion of the third gate layer 1500 in FIG. 8. The second interlayer insulating layer 119 may include an insulating material. In an embodiment, for example, the second interlayer insulating layer 119 may include silicon oxide, silicon nitride, silicon oxynitride, aluminum oxide, or the like.

A first connection electrode layer 1600 shown in FIG. 9 may be disposed on the second interlayer insulating layer 119. The first connection electrode layer 1600 may include a horizontal connection line 1610, a second transmission line 1620, a second initialization voltage line 1630, a third transmission line 1640, a fourth transmission line 1650, a fifth transmission line 1660, a sixth transmission line 1670, and a seventh transmission line 1680.

The horizontal connection line 1610 may extend in the second direction (the x-axis direction). The horizontal connection line 1610, together with a vertical connection line 1820 (see FIG. 10), may be used to transmit a data signal from the driving chip 20 to the data line DL at a corner portion, such as the bottom left or bottom right of the display area DA shown in FIG. 1. However, the horizontal connection line 1610 and the vertical connection line 1820 may be present even in pixels that are not located at the corner portion of the display area DA, and thus, most pixels may have the same or similar configuration.

The second transmission line 1620 may be electrically connected to the first semiconductor layer 1100 through a contact hole 1620CNT. A data signal Dm from a data line 1810 to be described below with reference to FIG. 10 may be transmitted to the first semiconductor layer 1100 through the second transmission line 1620 and applied to the switching transistor T2.

The second initialization voltage line 1630 may extend in the second direction (the x-axis direction). The second initialization voltage line 1630, which corresponds to the second initialization voltage line VL2 in FIG. 2, may apply the second initialization voltage Vint2 to the pixels. The second initialization voltage line 1630 may be electrically connected to the first semiconductor layer 1100 through a contact hole 1630CNT, and thus, the second initialization voltage Vint2 may be transmitted to the first semiconductor layer 1100 and applied to the second initialization transistor T7.

The third transmission line 1640 may electrically connect the second semiconductor layer 1400 to the first transmission line 1540 through contact holes 1640CNT1 and 1640CNT2 defined at one side and the other side of the third transmission line 1640. Because the first transmission line 1540 is electrically connected to the first gate electrode 1220, which is a driving gate electrode, the third transmission line 1640 may electrically connect the first initialization semiconductor layer, which is a portion of the second semiconductor layer 1400, to the driving gate electrode. The first initialization voltage Vint1 may be transmitted to the first gate electrode 1220, which is a driving gate electrode, through the second semiconductor layer 1400, the third transmission line 1640, and the first transmission line 1540.

The fourth transmission line 1650 may electrically connect the second semiconductor layer 1400 to the first semiconductor layer 1100 through contact holes 1650CNT1 and 1650CNT2 defined at one side and the other side of the fourth transmission line 1650. In other words, the fourth transmission line 1650 may electrically connect the compensation transistor T3 and the driving transistor T1 to each other.

The fifth transmission line 1660 may extend in the second direction (the x-axis direction). The driving voltage ELVDD, which is a constant voltage from a driving voltage line 1830 to be described below with reference to FIG. 10, may be transmitted to the fifth transmission line 1660, and the fifth transmission line 1660 may be electrically connected to the first semiconductor layer 1100 through a contact hole 1660CNT1 and transmit the driving voltage ELVDD to the first semiconductor layer 1100, specifically, to the operation control transistor T5. In addition, the fifth transmission line 1660, which is electrically connected to the capacitor upper electrode 1330 (i.e., the second capacitor electrode CE2 in FIG. 2) through a contact hole 1660CNT2, may transmit the driving voltage ELVDD to the capacitor upper electrode 1330.

The sixth transmission line 1670 may be electrically connected to the first semiconductor layer 1100 through a contact hole 1670CNT. The sixth transmission line 1670 may transmit the driving current or the second initialization voltage Vint2 from the first semiconductor layer 1100 to the organic light-emitting diode OLED.

The seventh transmission line 1680 may be electrically connected to the second semiconductor layer 1400 through contact holes 1680CNT2 and 1680CNT3. In addition, the seventh transmission line 1680 may be electrically connected to the first initialization voltage line 1340 in FIG. 6 through a contact hole 1680CNT1. Accordingly, the seventh transmission line 1680 may transmit the first initialization voltage Vint1 from the first initialization voltage line 1340 to the first initialization transistor T4.

The first connection electrode layer 1600 may include a metal, an alloy, a conductive metal oxide, a transparent conductive material, or the like. In an embodiment, for example, the first connection electrode layer 1600 may include Ag, an Ag-containing alloy, Mo, a Mo-containing alloy, Al, an Al-containing alloy, AlN, W, WN, Cu, Ni, Cr, CrN, Ti, Ta, Pt, Sc, ITO, IZO, or the like. The first connection electrode layer 1600 may have a multi-layer structure, such as a two-layer structure of a Ti layer and an Al layer, or a three-layer structure of a Ti layer, an Al layer, and another Ti layer.

In an embodiment, as shown in FIG. 11, a third interlayer insulating layer 121 may be disposed on the second interlayer insulating layer 119 and cover the first connection electrode layer 1600. The third interlayer insulating layer 121 may include an insulating material. In an embodiment, for example, the third interlayer insulating layer 121 may include silicon oxide, silicon nitride, silicon oxynitride, aluminum oxide, or the like. In an embodiment, the third interlayer insulating layer 121 may include an organic insulating material. In an embodiment, for example, the third interlayer insulating layer 121 may include photoresist, benzocyclobutene (BCB), polyimide, hexamethyldisiloxane (HMDSO), polymethylmethacrylate (PMMA), polystyrene, a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, or any blends thereof.

A second connection electrode layer 1800 shown in FIG. 10 may be located on the third interlayer insulating layer 121. The second connection electrode layer 1800 may include a data line 1810, a vertical connection line 1820, a driving voltage line 1830, and a tenth transmission line 1840.

The data line 1810 may extend in a first direction (the y-axis direction). The data line 1810 may correspond to the data line DL in FIGS. 1 and 2. The data line 1810 may be electrically connected to the second transmission lie 1620 through a contact hole 1810CNT, and a data signal Dm from the data line 1810 may be transmitted to the semiconductor layer 1100 through the second transmission line 1620 and applied to the switching transistor T2.

The vertical connection line 1820 may extend substantially in the first direction (the y-axis direction). In an embodiment, as described above, the vertical connection line 1820, together with the horizontal connection line 1610, may transmit a data signal from the driving chip 20 to the data line DL at a corner portion, such as the bottom left or bottom right of the display area DA shown in FIG. 1. However, the horizontal connection line 1610 and the vertical connection line 1820 may be present even in pixels that are not located at the corner portion of the display area DA, and thus, most pixels may have a same or similar configuration as each other.

The driving voltage line 1830 may extend substantially in the first direction (the y-axis direction). The driving voltage line 1830 may correspond to the driving voltage line PL in FIGS. 1 and 2. The driving voltage line 1830 may apply the driving voltage ELVDD to the pixels. The driving voltage line 1830 may be electrically connected to the fifth transmission line 1660 through a contact hole 1830CNT, and thus, as described above, the driving voltage ELVDD may be transmitted to the operation control transistor T5 and the capacitor upper electrode 1330. The driving voltage line 1830 of the first pixel circuit PC1 may be integrally formed with the driving voltage line 1830 of the second pixel circuit PC2 adjacent thereto as a single unitary indivisible part.

The tenth transmission line 1840 may be electrically connected to the sixth transmission line 1670 through a contact hole 1840CNT1 and receive the driving current or the second initialization voltage Vint2 from the first semiconductor layer 1100 through the sixth transmission line 1670. The tenth transmission line 1840 may transmit the driving current or the second initialization voltage Vint2 from the first semiconductor layer 1100 to the pixel electrode 310 of the organic light-emitting diode OLED through a contact hole 1840CNT2 defined in an insulating layer disposed over the tenth transmission line 1840.

The second connection electrode layer 1800 may include a metal, an alloy, a conductive metal oxide, a transparent conductive material, or the like. In an embodiment, for example, the second connection electrode layer 1800 may include Ag, an Ag-containing alloy, Mo, a Mo-containing alloy, Al, an Al-containing alloy, AlN, W, WN, Cu, Ni, Cr, CrN, Ti, Ta, Pt, Sc, ITO, IZO, or the like. The second connection electrode layer 1800 may have a multi-layer structure, such as a two-layer structure of a Ti layer and an Al layer, or a three-layer structure of a Ti layer, an Al layer, and another Ti layer.

A planarization insulating layer 125 shown in FIG. 11 may be disposed on the third interlayer insulating layer 121 and cover the second connection electrode layer 1800. The planarization insulating layer 125 may include an organic insulating material. In an embodiment, for example, the planarization insulating layer 125 may include photoresist, BCB, polyimide, HMDSO, PMMA, polystyrene, a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, or any blends thereof.

As shown in FIG. 11, an organic light-emitting diode OLED may be located on the planarization insulating layer 125. The organic light-emitting diode OLED may include a pixel electrode 310, an intermediate layer 320 including an emission layer, and an opposite electrode 330.

The pixel electrode 310 may include a (semi-) light-transmitting electrode or a reflective electrode. In an embodiment, for example, the pixel electrode 310 may include a reflective layer and a transparent or semi-transparent electrode layer disposed on the reflective layer, the reflective layer including Ag, magnesium (Mg), Al, Pt, palladium (Pd), gold (Au), Ni, neodymium (Nd), iridium (Ir), Cr, or a compound thereof. The transparent or semi-transparent electrode layer may include at least one selected from indium tin oxide (ITO), indium zinc oxide (IZO), zinc oxide (ZnO or ZnO2), indium oxide (In2O3), indium gallium oxide (IGO), and aluminum zinc oxide (AZO). In an embodiment, for example, the pixel electrode 310 may have a three-layer structure of an ITO layer, an Ag layer, and another ITO layer.

A pixel-defining layer 127 may be disposed on the planarization insulating layer 125. The pixel-defining layer 127 may prevent an arc or the like from occurring at the edge of the pixel electrode 310 by increasing a distance between the edge of the pixel electrode 310 and the opposite electrode 330 above the pixel electrode 310.

The pixel-defining layer 127 may include one or more organic insulating materials selected from polyimide, polyamide, an acryl-based resin, BCB, and a phenolic resin, and may be formed by a method such as spin coating.

At least a portion of the intermediate layer 320 of the organic light-emitting diode OLED may be located within an opening defined by the pixel-defining layer 127. An emission area EA of the organic light-emitting diode OLED may be defined by the opening of the pixel-defining layer 127.

The intermediate layer 320 may include an emission layer. The emission layer may include an organic material including a fluorescent or phosphorous material emitting red, green, blue, or white light. The emission layer may include a low-molecular weight organic material or a polymer organic material, and a functional layer, such as a hole transport layer (HTL), a hole injection layer (HIL), an electron transport layer (ETL), or an electron injection layer (EIL), may selectively be further disposed below and/or over the emission layer.

The emission layer may have a patterned shape to correspond to each of the pixel electrodes 310. A layer included in the intermediate layer 320 except for the emission layer may be integrally or commonly formed as a single body over a plurality of pixel electrodes 310, and various modifications may be made.

The opposite electrode 330 may be a light-transmitting electrode or a reflective electrode. In an embodiment, for example, the opposite electrode 330 may be a transparent or semi-transparent electrode and may include lithium (Li), calcium (Ca), lithium fluoride (LiF), Al, Ag, Mg, or a compound thereof. In addition, the opposite electrode 330 may further include a transparent conductive oxide (TCO) layer, which may include ITO, IZO, ZnO, ZnO2, In2O3, or the like. The opposite electrode 330 may be integrally formed as a single body throughout the entire surface of the display area DA and may be disposed over the intermediate layer 320 and the pixel-defining layer 127.

The organic light-emitting diode OLED may be covered with a thin-film encapsulation layer (not shown) or a sealing substrate. In an embodiment, the thin-film encapsulation layer may include at least one inorganic encapsulation layer and at least one organic encapsulation layer. In an embodiment, for example, the thin-film encapsulation layer may include a first inorganic encapsulation layer, a second inorganic encapsulation layer, and an organic encapsulation layer therebetween.

The first inorganic encapsulation layer and the second inorganic encapsulation layer may each include one or more inorganic insulating materials, such as silicon oxide (SiO2), silicon nitride (SiNx), silicon oxynitride (SiOxNy), aluminum oxide (Al2O3), titanium oxide (TiO2), tantalum oxide (Ta2O5), hafnium oxide (HfO2), or zinc oxide (ZnO2), and may be formed by chemical vapor deposition (CVD) or the like. The organic encapsulation layer may include a polymer-based material. Examples of the polymer-based material may include silicone-based resin, acrylic resin (e.g., polymethyl methacrylate or polyacrylic acid), epoxy-based resin, polyimide, and polyethylene.

Each of the first inorganic encapsulation layer, the organic encapsulation layer, and the second inorganic encapsulation layer may be integrally formed as a single body to cover the display area DA.

In an embodiment, as shown in FIG. 11, the substrate 100 may include two layers 101 and 102 including the polymer resin described above and a substrate intermediate layer 103 interposed between the layers 101 and 102. That is, the substrate 100 may include a first substrate 101 (i.e., the layer 101), a second substrate 102 (i.e., the layer 102) disposed over (or opposite to) the first substrate 101, and a substrate intermediate layer 103 disposed therebetween. The substrate intermediate layer 103 may bond the two layers 101 and 102 to each other and may also function as a barrier to prevent external impurities from passing through the substrate 100. In addition, the substrate 100 may include a first intermediate electrode 101′ interposed between the substrate intermediate layer 103 and the first substrate 101, and a second intermediate electrode 102′ interposed between the substrate intermediate layer 103 and the second substrate 102.

In an embodiment, the substrate intermediate layer 103 may include amorphous silicon or crystalline silicon. In such an embodiment, when light such as ultraviolet rays from the outside is radiated to the substrate intermediate layer 103, electron-hole pairs may be formed within the substrate intermediate layer 103. At this time, when on-bias is applied from the driving transistor T1 and the like above the substrate intermediate layer 103, electrons or holes may move within the substrate intermediate layer 103. The electrons or holes that move in this way may affect the driving transistor T1 and the like above the substrate intermediate layer 103 and deteriorate the quality of images displayed by the display apparatus.

For example, when a high signal is applied to the first gate electrode 1220, which is the driving gate electrode of the driving transistor T1, which is a P-type transistor, the driving transistor T1 is turned off, and when a low signal is applied to the first gate electrode 1220, the driving transistor T1 is turned on. When the driving transistor T1 is turned on, holes that are carriers are located in the channel region that overlaps the first gate electrode 1220 of the first semiconductor layer 1100. In this case, a polarization phenomenon occurs in the second substrate 102, and thus, a portion of the second substrate 102 in the direction to the first semiconductor layer 1100 is relatively in a negative (−) state and a portion of the second substrate 102 in the direction to the substrate intermediate layer 103 is relatively in a positive (+) state.

As described above, when light such as ultraviolet rays from the outside is radiated to the substrate intermediate layer 103, electron-hole pairs are generated within the substrate intermediate layer 103, and thus, a portion of the second substrate 102 in the direction of the substrate intermediate layer 103 is relatively in a positive (+) state. Therefore, when the first intermediate electrode 101′ and the second intermediate electrode 102′ are not present, electrons are collected in a portion of the substrate intermediate layer 103 that overlaps the first gate electrode 1220. In this case, the electrons collected in the portion of the substrate intermediate layer 103 that overlaps the first gate electrode 1220 affect the driving transistor T1 by changing the threshold voltage thereof, thereby affecting the luminance of a display element electrically connected to the driving transistor T1, that is, the organic light-emitting diode OLED. As a result, the quality of images displayed in the display area DA may unintentionally deteriorate. For reference, when the driving transistor T1 is a P-type transistor, holes may be collected in the portion of the substrate intermediate layer 103 that overlaps the first gate electrode 1220, thereby affecting the driving transistor T1 in a similar way.

In an embodiment of the invention, as described above, the display apparatus includes the first intermediate electrode 101′ and the second intermediate electrode 102′, such problems may be effectively prevented or substantially reduced. In an embodiment, as shown in FIG. 11, the display apparatus includes the first intermediate electrode 101′ interposed between the substrate intermediate layer 103 and the first substrate 101 and corresponding to the first gate electrode 1220, and the second intermediate electrode 102′ interposed between the substrate intermediate layer 103 and the second substrate 102 and corresponding to the first gate electrode 1220. Because the first intermediate electrode 101′ and the second intermediate electrode 102′ are conductors, electrons or holes collected in a portion of the substrate intermediate layer 103 interposed between the first intermediate electrode 101′ and the second intermediate electrode 102′ may be effectively prevented from affecting the driving transistor T1 above the substrate intermediate layer 103.

The first intermediate electrodes 101′ and the second intermediate electrodes 102′ may each include Ag, an Ag-containing alloy, Mo, a Mo-containing alloy, Al, an Al-containing alloy, AlN, W, WN, Cu, Ni, Cr, CrN, Ti, Ta, Pt, Sc, ITO, IZO, or the like. The first intermediate electrode 101′ and the second intermediate electrode 102′ may each have a multi-layer structure if desired. In an embodiment, for example, the first intermediate electrode 101′ and the second intermediate electrode 102′ may each have a multi-layer structure, such as a two-layer structure of Ti/Al layers or Mo/Al layers or a three-layer structure of Ti/Al/Ti layers or Mo/Al/Mo layers.

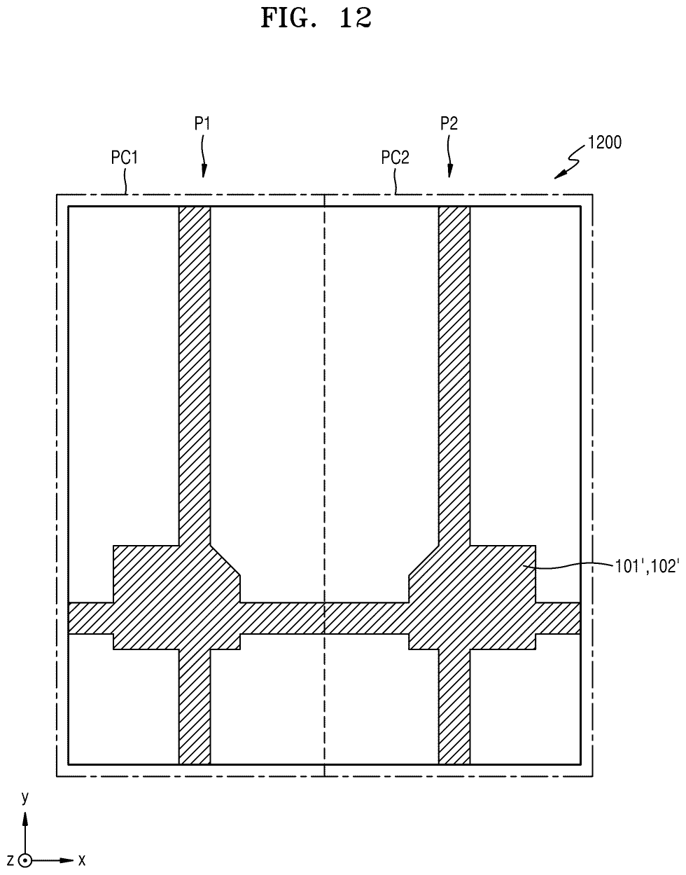

Because the first intermediate electrode 101′ and the second intermediate electrode 102′ effectively prevent or substantially reduce the influence of electrons or holes collected in the substrate intermediate layer 103 on the driving transistor T1 above the substrate intermediate layer 103, as shown in FIG. 12, which is a plan view schematically illustrating one component of the substrate 100 included in the display apparatus of FIG. 1, when viewed in a direction (the z-axis direction) perpendicular to the substrate 100, each of the first intermediate electrode 101′ and the second intermediate electrode 102′ may overlap the first gate electrode 1220. As described above, electrons or holes may be effectively prevented from being collected in the portion of the substrate intermediate layer 103 that overlaps the first gate electrode 1220 by using the first intermediate electrode 101′ and the second intermediate electrode 102′.

For reference, in FIG. 12, the first intermediate electrodes 101′ of a plurality of pixels are connected to each other by connection parts extending in the x-axis direction and connection parts extending in the y-axis direction and thus integrally formed as a single body in a substantially mesh form. In the plurality of pixels, the second intermediate electrodes 102′ may also be connected to each other by connection parts and thus integrally formed as a single body in a substantially mesh form. In another embodiment, only the first intermediate electrodes 101′ located in the same row may be connected to each other by connection parts extending in the x-axis direction, and only the second intermediate electrodes 102′ located in a same row may be connected to each other by connection parts extending in the x-axis direction. The same applies to embodiments to be described below and modifications thereof.

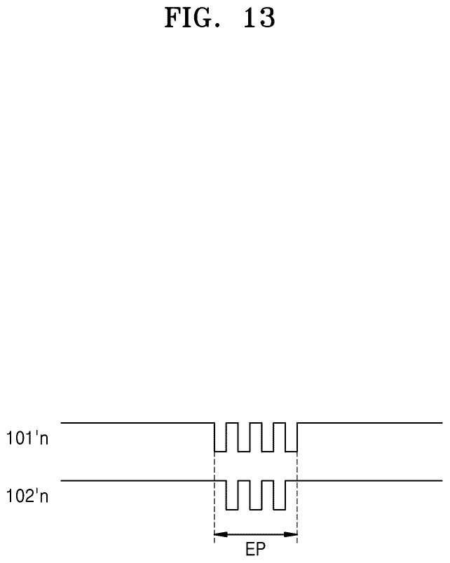

FIG. 13 is a waveform diagram schematically showing electrical signals that may be applied to the first intermediate electrode 101′ and the second intermediate electrode 102′, which are components of FIG. 12 included in the display apparatus of FIG. 1. In FIG. 13, a first electrical signal 101′n that may be applied to the first intermediate electrode 101′ and a second electrical signal 102′n that may be applied to the second intermediate electrode 102′ are shown.

As shown in FIG. 13, during an equilibrium period EP, the polarity of the first electrical signal 101′n applied to the first intermediate electrode 101′ may be different from the polarity of the second electrical signal 102′n applied to the second intermediate electrode 102′. In an embodiment, for example, when the first electrical signal 101′n has one of a positive (+) potential and a negative (−) potential, the second electrical signal 102′n may have the other of the positive (+) potential and the negative (−) potential. Here, the equilibrium period (EP) may refer to a period of applying electrical signals to the first intermediate electrode 101′ and the second intermediate electrode 102′ to prevent or reduce the influence of electrons or holes collected in the substrate intermediate layer 103 on the driving transistor T1 above the substrate intermediate layer 103. During a period or periods other than the equilibrium period EP, electrical signals having a same polarity may be applied to the first intermediate electrode 101′ and the second intermediate electrode 102′, or no electrical signal may be applied to the first intermediate electrode 101′ and the second intermediate electrode 102′. FIG. 13 shows, an embodiment as an example, where a high signal is applied to the first intermediate electrode 101′ and the second intermediate electrode 102′ during periods other than the equilibrium period EP. In this way, the fact that an electrical signal is applied to the first intermediate electrode 101′ may mean that an electrical signal is applied to the first intermediate electrode 101′ during the equilibrium period EP.

In such an embodiment, during the equilibrium period EP, the polarity of the first electrical signal 101′n applied to the first intermediate electrode 101′ is different from the polarity of the second electrical signal 102′n applied to the second intermediate electrode 102′, such that the influence of electrons or holes collected in the substrate intermediate layer 103 on the driving transistor T1 above the substrate intermediate layer 103 may be effectively prevented or substantially reduced. In particular, as shown in FIG. 13, during the equilibrium period EP, the polarity of the first electrical signal 101′n applied to the first intermediate electrode 101′ may be alternately changed and the polarity of the second electrical signal 102′n applied to the second intermediate electrode 102′ may be opposite to the polarity of the first electrical signal 101′n applied to the first intermediate electrode 101′.

In such an embodiment, during the equilibrium period EP, the direction of an electric field applied, by the first intermediate electrode 101′ and the second intermediate electrode 102′, to a portion of the substrate intermediate layer 103 between the first intermediate electrode 101′ and the second intermediate electrode 102′ is alternately changed, and accordingly, the gathering of electrons or holes in the portion of the substrate intermediate layer 103 between the first intermediate electrode 101′ and the second intermediate electrode 102′ may be effectively prevented or substantially reduced. As a result, the effect of preventing or reducing the influence of electrons or holes collected in the substrate intermediate layer 103 on the driving transistor T1 above the substrate intermediate layer 103 may be further increased.

Alternatively, during the equilibrium period EP, the potential of the first electrical signal 101′n applied to the first intermediate electrode 101′ may be different from the potential of the second electrical signal 102′n applied to the second intermediate electrode 102′. During a period other than the equilibrium period EP, electrical signals having a same potential may be applied to the first intermediate electrode 101′ and the second intermediate electrode 102′, or no electrical signal may be applied to the first intermediate electrode 101′ and the second intermediate electrode 102′. In this way, the fact that an electrical signal is applied to the first intermediate electrode 101′ may mean that an electrical signal is applied to the first intermediate electrode 101′ during the equilibrium period EP.

In an embodiment, during the equilibrium period EP, the potential of the first electrical signal 101′n applied to the first intermediate electrode 101′ is different from the potential of the second electrical signal 102′n applied to the second intermediate electrode 102′, such that the influence of electrons or holes collected in the substrate intermediate layer 103 on the driving transistor T1 above the substrate intermediate layer 103 may be effectively prevented or substantially reduced. In particular, as shown in FIG. 13, during the equilibrium period EP, the potential of the first electrical signal 101′n applied to the first intermediate electrode 101′ may be alternately changed to a first potential and a second potential. When the potential of the first electrical signal 101′n applied to the first intermediate electrode 101′ is the first potential, the potential of the second electrical signal 102′n applied to the second intermediate electrode 102′ may be set to the second potential, and when the potential of the first electrical signal 101′n applied to the first intermediate electrode 101′ is the second potential, the potential of the second electrical signal applied to the second intermediate electrode 102′ may be set to the first potential.

In this case, during the equilibrium period EP, the direction of an electric field applied, by the first intermediate electrode 101′ and the second intermediate electrode 102′, to a portion of the substrate intermediate layer 103 between the first intermediate electrode 101′ and the second intermediate electrode 102′ is alternately changed, and accordingly, the gathering of electrons or holes in the portion of the substrate intermediate layer 103 between the first intermediate electrode 101′ and the second intermediate electrode 102′ may be effectively prevented or substantially reduced. As a result, the effect of preventing or reducing the influence of electrons or holes collected in the substrate intermediate layer 103 on the driving transistor T1 above the substrate intermediate layer 103 may be further increased.

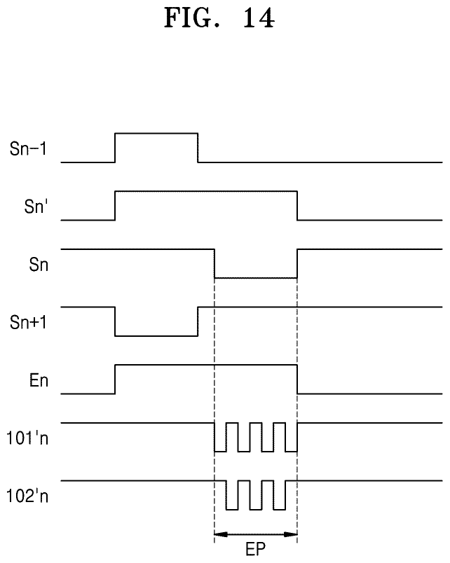

FIG. 14 is a waveform diagram schematically showing electrical signals that may be applied to the equivalent circuit of FIG. 2 and the components of FIG. 12. That is, FIG. 14 is a waveform diagram schematically showing electrical signals that may be applied to pixel circuits of pixels located in an n-th row, the first intermediate electrode 101′, and the second intermediate electrode 102′ according to an embodiment. In such an embodiment, unlike shown in FIG. 12, only the first intermediate electrodes 101′ located in a same row may be electrically connected to or integrated with each other by connection parts extending in the x-axis direction, and the first intermediate electrodes 101′ located in different rows may not be connected to each other.

During an initialization period, the previous scan signal Sn−1 is supplied through the previous scan line SLp, the next scan signal Sn+1 is supplied through the next scan line SLn, and the second scan signal Sn′ is supplied through the second scan line SL2. Accordingly, in response to the previous scan signal Sn−1, the first initialization transistor T4 is turned on, and thus, the driving transistor T1 is initialized by the first initialization voltage Vint1 supplied from the first initialization voltage line VL1. In addition, in response to the next scan signal Sn+1, the second initialization transistor T7 is turned on, and thus, the pixel electrode 310 of the organic light-emitting diode OLED is turned on by the second initialization voltage Vint2 supplied from the second initialization voltage line VL2. In addition, the compensation transistor T3 is turned on by the second scan signal Sn′, and the driving transistor T1 is diode-connected by the turned-on compensation transistor T3 and is biased in a forward direction.

During a data programming period, when the first scan signal Sn is supplied through the first scan line SL1, the switching transistor T2 is turned on in response to the first scan signal Sn. The second scan signal Sn′ also continues to be supplied through the second scan line SL2 to keep the compensation transistor T3 turned on, and thus, the driving transistor T1 continues to be diode-connected and forward biased. Then, a compensation voltage (Dm+Vth, where Vth has a negative value), which is obtained by subtracting a threshold voltage (Vth) of the driving transistor T1 from the data signal Dm received through the data line DL, may be applied to the driving gate electrode of the driving transistor T1. The driving voltage ELVDD and the compensation voltage (Dm+Vth) are respectively applied to opposite ends of the storage capacitor Cst, and a charge corresponding to a voltage difference between the opposite ends of the storage capacitor Cst may be stored in the storage capacitor Cst.

During the data programming period, the potential of the first electrical signal 101′n applied to the first intermediate electrode 101′ may be alternately changed to a first potential and a second potential. The first potential may be, for example, a low level, and the second potential may be, for example, a high level. When the potential of the first electrical signal 101′n applied to the first intermediate electrode 101′ is the first potential, the potential of the second electrical signal 102′n applied to the second intermediate electrode 102′ may be set to the second potential, and when the potential of the first electrical signal 101′n applied to the first intermediate electrode 101′ is the second potential, the potential of the second electrical signal applied to the second intermediate electrode 102′ may be set to the first potential.

However, alternatively, during the data programming period, the polarity of the first electrical signal 101′n applied to the first intermediate electrode 101′ may be alternately changed. That is, the potential of the first electrical signal 101′n may be alternately changed to a positive (+) potential and a negative (−) potential. In this case, the polarity of the second electrical signal 102′n applied to the second intermediate electrode 102′ may be opposite to the polarity of the first electrical signal 101′n applied to the first intermediate electrode 101′.

The data programming period may be referred to as the equilibrium period EP described above. Accordingly, when a compensation voltage (Dm+Vth), which is obtained by subtracting a threshold voltage Vth of the driving transistor T1 from the data signal Dm received through the data line DL, is applied to the driving gate electrode of the driving transistor T1 to thereby store charges corresponding to the difference between the driving voltage ELVDD and the compensation voltage (Dm+Vth) in the storage capacitor Cst, the gathering of electrons or holes in the portion of the substrate intermediate layer 103 between the first intermediate electrode 101′ and the second intermediate electrode 102′ may be effectively prevented or substantially reduced. As a result, the effect of preventing or reducing the influence of electrons or holes collected in the substrate intermediate layer 103 on the driving transistor T1 above the substrate intermediate layer 103 may be increased.

Thereafter, during an emission period, the operation control transistor T5 and the emission control transistor T6 may be turned on in response to the emission control signal En received through the emission control line EL. A driving current corresponding to a voltage difference between the voltage of the driving gate electrode of the driving transistor T1 and the driving voltage ELVDD may be generated, and the driving current may be supplied to the organic light-emitting diode OLED through the emission control transistor T6. As a result, the organic light-emitting diode OLED may generate light having a luminance corresponding to the amount of driving current supplied from the driving transistor T1.

The organic light-emitting diode OLED may repeat this process and generate light having a corresponding luminance, allowing an image to be displayed in the display area DA.

In an embodiment, as described above, the compensation voltage (Dm+Vth), which is obtained by subtracting the threshold voltage (Vth) of the driving transistor T1 from the data signal Dm received through the data line DL during the data programming period, may be applied to the driving gate electrode of the driving transistor T1, and thus, the driving transistor T1 may be turned on. The driving transistor T1 may be maintained in a turned-on state by the storage capacitor Cst even during an emission period that follows the data programming period.

Therefore, while the driving transistor T1 is turned on, the first electrical signal 101′n described above may be applied to the first intermediate electrode 101′ and the second electrical signal 102′n described above may be applied to the second intermediate electrode 102′. That is, during a period from a time point at which the driving transistor T1 is turned on (i.e., a time point at which a state of the driving transistor T1 is changed from a turn-off state to a turn-on state) to a time point at which the driving transistor T1 is turned off (i.e., a time point at which the state of the driving transistor T1 is changed from the turn-off state to the turn-on state), the first electrical signal 101′n described above may be applied to the first intermediate electrode 101′ and the second electrical signal 102′n described above may be applied to the second intermediate electrode 102′. In an embodiment, as shown in FIG. 14, for at least the data programming period after the driving transistor T1 is turned on, the first electrical signal 101′n described above may be applied to the first intermediate electrode 101′ and the second electrical signal 102′n described above may be applied to the second intermediate electrode 102′.

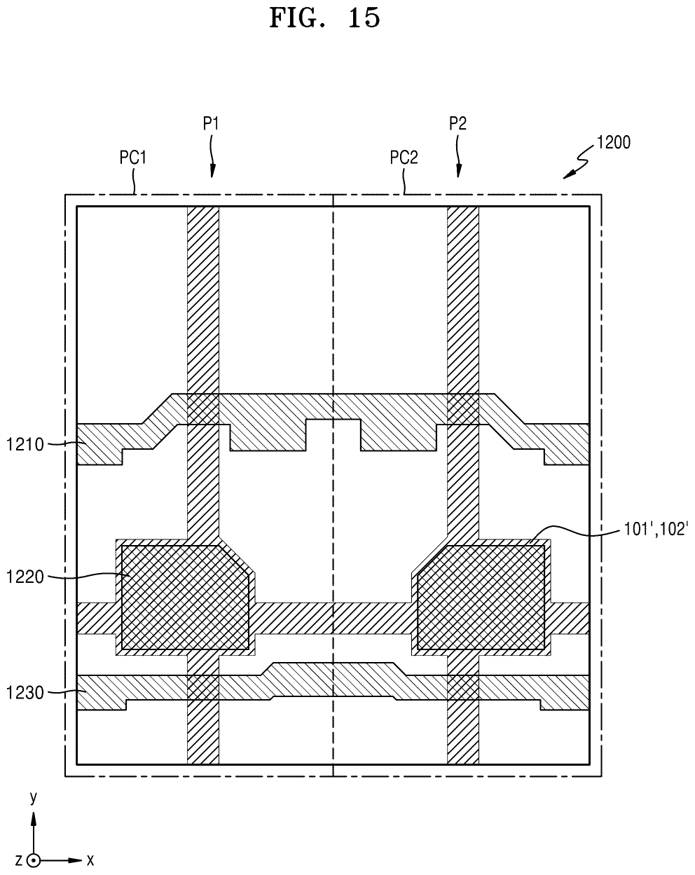

FIG. 15 is a plan view schematically showing some components included in a display apparatus according to an embodiment, and shows the first intermediate electrode 101′ and the second intermediate electrode 102′ overlapping the first gate layer 1200. As shown in FIG. 15, when viewed in a direction (the z-axis direction) perpendicular to the substrate 100, the first gate electrode 1220, which is a driving gate electrode, may be located within the second intermediate electrode 102′. The first gate electrode 1220 may also be located within the first intermediate electrode 101′. As described above, electrons or holes may be effectively prevented from being collected in a portion of the substrate intermediate layer 103 that overlaps the first gate electrode 1220 by using the first intermediate electrode 101′ and the second intermediate electrode 102′.

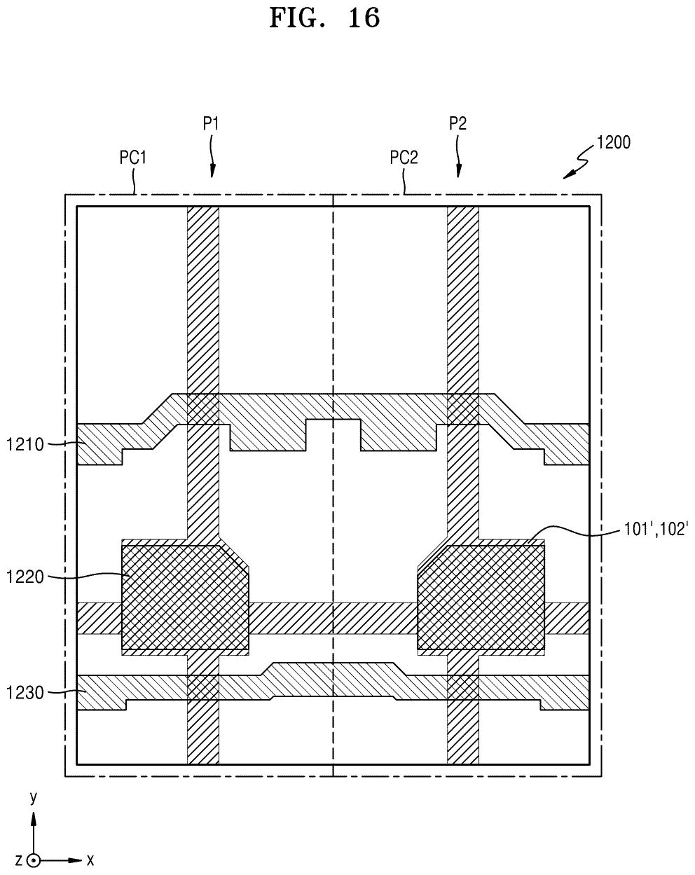

Alternatively, as shown in FIG. 16, which is a plan view schematically showing some components included in a display apparatus according to an embodiment and shows the first intermediate electrode 101′ and the second intermediate electrode 102′ overlapping the first gate layer 1200, when viewed in the direction (the z-axis direction) perpendicular to the substrate 100, a portion of the edge of the first gate electrode 1220, the portion overlapping the first semiconductor layer 1100, may overlap the edge of the second intermediate electrode 102′. This is to ensure that a portion of the first semiconductor layer 1100 overlapping the first gate electrode 1220, that is, at least the channel region of the driving transistor T1, is located within the second intermediate electrode 102′ when viewed in the direction (the z-axis direction) perpendicular to the substrate 100. For reference, in FIG. 11, which is a cross-sectional view, a length L of each of the first intermediate electrode 101′ and the second intermediate electrode 102′ in the cross-sectional view is shown to be the same as the length of the first gate electrode 1220 in the cross-sectional view, and a portion of the edge of the first gate electrode 1220, the portion overlapping the first semiconductor layer 1100, is shown to overlap the edge of the second intermediate electrode 102′.

As described above with reference to FIG. 1, the driving chip 20, which is a driving driver, may be disposed in the peripheral area PA of the display panel 10. The first intermediate electrode 101′ and the second intermediate electrode 102′ may be electrically connected to the driving chip 20. That is, the driving chip 20 may apply the first electrical signal 101′n described above to the first intermediate electrode 101′ and the second electrical signal 102′n described above to the second intermediate electrode 102′.

As described above, the driving chip 20 may generate electrical signals required by a scan driving circuit and/or an emission control driving circuit and apply the electrical signals to the scan driving circuit and/or the emission control driving circuit. Accordingly, the scan driving circuit and/or the emission control driving circuit may apply the first electrical signal 101′n described above to the first intermediate electrode 101′ and the second electrical signal 102′n described above to the second intermediate electrode 102′. In an embodiment, for example, the scan driving circuit may generate a low signal or a high signal and apply the first scan signal Sn to the first scan line SL1, and thus, the first electrical signal 101′n and/or the second electrical signal 102′n may be generated using the low signal or the high signal. In an embodiment, for example, the high signal may be an electrical signal of +5 volts (V), and the low signal may be an electrical signal of −1 V. Alternatively, by using the first power voltage (or driving voltage) ELVDD having a negative potential and the second power voltage (or common voltage) ELVSS having a positive potential, the first electrical signal 101′n and/or the second electrical signal 102′n may be generated.

For reference, an electrical signal applied to the first intermediate electrode 101′ may be applied to the first intermediate electrode 101′ through a contact hole defined in the second substrate 102, the substrate intermediate layer 103, and the like, and an electrical signal applied to the second intermediate electrode 102′ may be applied to the second intermediate electrode 102′ through a contact hole formed in the second substrate 102 and the like.

Embodiments of the disclosure is not limited to those described above. For example, a thin-film transistor substrate, which includes the substrate 100, the first semiconductor layer 1100, and the first gate electrode 1220, described above, the substrate 100 including the first substrate 101, the second substrate 102, the substrate intermediate layer 103, the first intermediate electrode 101′, and the second intermediate electrode 102′, described above, may also be said to fall within the scope of the disclosure. Features of the first substrate 101, the second substrate 102, the substrate intermediate layer 103, the first intermediate electrode 101′, the second intermediate electrode 102′, the first semiconductor layer 1100, and the first gate electrode 1220 described above may also be applied to the components of the thin-film transistor substrate.

According to the embodiments of the disclosure described above, a thin-film transistor substrate in which the influence of external light is reduced, and a display apparatus including the thin-film transistor substrate may be implemented.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A thin-film transistor substrate comprising:
a substrate;
a semiconductor layer disposed on the substrate; and
a gate electrode disposed on the semiconductor layer,
wherein
the substrate comprises:
a first substrate;
a second substrate disposed opposite to the first substrate;
a substrate intermediate layer interposed between the first substrate and the second substrate;
a first intermediate electrode interposed between the substrate intermediate layer and the first substrate and corresponding to the gate electrode; and
a second intermediate electrode interposed between the substrate intermediate layer and the second substrate and corresponding to the gate electrode.

2. The thin-film transistor substrate of claim 1, wherein each of the first intermediate electrode and the second intermediate electrode overlaps the gate electrode when viewed in a direction perpendicular to the substrate.

3. The thin-film transistor substrate of claim 2, wherein the gate electrode is located within the second intermediate electrode when viewed in the direction perpendicular to the substrate.

4. The thin-film transistor substrate of claim 2, wherein, when viewed in the direction perpendicular to the substrate, a portion of an edge of the gate electrode overlaps the semiconductor layer and the portion of the edge of the gate electrode overlaps an edge of the second intermediate electrode.

5. The thin-film transistor substrate of claim 1, wherein the substrate intermediate layer comprises amorphous silicon or crystalline silicon.

6. The thin-film transistor substrate of claim 1, wherein electrical signals are applied to the first intermediate electrode and the second intermediate electrode, and
a polarity of an electrical signal applied to the first intermediate electrode is different from a polarity of an electrical signal applied to the second intermediate electrode.

7. The thin-film transistor substrate of claim 1, wherein electrical signals are applied to the first intermediate electrode and the second intermediate electrode, and
a potential of an electrical signal applied to the first intermediate electrode is different from a potential of an electrical signal applied to the second intermediate electrode.

8. The thin-film transistor substrate of claim 1, wherein electrical signals are applied to the first intermediate electrode and the second intermediate electrode while a transistor including the semiconductor layer and the gate electrode is turned on.

9. The thin-film transistor substrate of claim 8, wherein a polarity of an electrical signal applied to the first intermediate electrode is alternately changed during a period from a time point at which the transistor is turned on to a time point at which the transistor is turned off.

10. The thin-film transistor substrate of claim 9, wherein a polarity of an electrical signal applied to the second intermediate electrode is opposite to the polarity of the electrical signal applied to the first intermediate electrode.

11. The thin-film transistor substrate of claim 8, wherein a potential of an electrical signal applied to the first intermediate electrode is alternately changed during a period from a time point at which the transistor is turned on to a time point at which the transistor is turned off.

12. The thin-film transistor substrate of claim 11, wherein the potential of the electrical signal applied to the first intermediate electrode is alternately changed between a first potential and a second potential,
wherein, when the potential of the electrical signal applied to the first intermediate electrode is the first potential, the potential of the electrical signal applied to the second intermediate electrode is the second potential, and when the potential of the electrical signal applied to the first intermediate electrode is the second potential, the potential of the electrical signal applied to the second intermediate electrode is the first potential.

13. A display apparatus comprising:
the thin-film transistor substrate of claim 1; and
a pixel electrode electrically connected to the semiconductor layer.

14. The display apparatus of claim 13, wherein the pixel electrode is electrically connected to a conductive layer which contacts the semiconductor layer.

15. The display apparatus of claim 13, wherein the semiconductor layer and the gate electrode are included in a driving transistor.

16. The display apparatus of claim 13, wherein the substrate includes a display area and a peripheral area outside the display area,
wherein the display apparatus further comprises a driving driver located in the peripheral area, and
wherein the first intermediate electrode and the second intermediate electrode are electrically connected to the driving driver.

17. The display apparatus of claim 16, wherein the driving driver applies a first electrical signal to the first intermediate electrode and a second electrical signal to the second intermediate electrode, wherein a polarity of the first electrical signal is different from a polarity of the second electrical signal.

18. The display apparatus of claim 16, wherein the driving driver applies a first electrical signal to the first intermediate electrode and a second electrical signal to the second intermediate electrode, wherein a potential of the first electrical signal is different from a potential of the second electrical signal.

19. The display apparatus of claim 16, wherein the driving driver applies a first electrical signal to the first intermediate electrode and a second electrical signal to the second intermediate electrode while a transistor including the semiconductor layer and a gate electrode is turned on.

20. The display apparatus of claim 19, wherein the driving driver applies an electrical signal having an alternately changing polarity to the first intermediate electrode from a time point at which the transistor is turned on to a time point at which the transistor is turned off.

21. The display apparatus of claim 20, wherein the driving driver applies, to the second intermediate electrode, an electrical signal having a polarity opposite to the polarity of the electrical signal applied to the first intermediate electrode.

22. The display apparatus of claim 19, wherein the driving driver applies, to the first intermediate electrode, an electrical signal having an alternately changing potential during a period from a time point at which the transistor is turned on to a time point at which the transistor is turned off.

23. The display apparatus of claim 22, wherein the alternately changing potential of the electrical signal is alternately changed between a first potential and a second potential,
wherein the driving driver further applies an electrical signal having the second potential to the second intermediate electrode when the potential of the electrical signal applied to the first intermediate electrode is the first potential, and applies an electrical signal having the first potential to the second intermediate electrode when the potential of the electrical signal applied to the first intermediate electrode is the second potential.
